(19) United States
(12) Patent Application Publication
(10) Pub. No.: US 2023/0050319 A1
(43) Pub. Date: Feb. 16, 2023

(54) SILICON CARBIDE SEMICONDUCTOR DEVICE

(71) Applicant: FUJI ELECTRIC CO., LTD., Kawasaki-shi (JP)

(72) Inventors: Masakazu BABA, Matsumoto-city (JP); Shinsuke HARADA, Tsukuba-city (JP)

(73) Assignee: FUJI ELECTRIC CO., LTD., Kawasaki-shi (JP)

(21) Appl. No.: 17/978,079

(22) Filed: Oct. 31, 2022

Related U.S. Application Data
(63) Continuation of application No. PCT/JP2021/042465, filed on Nov. 18, 2021.

(30) Foreign Application Priority Data
Nov. 18, 2020 (JP) 2020-191731

(51) Int. Cl. H01L 29/06; H01L 29/16; H01L 29/40; H01L 29/78; H01L 21/04; H01L 29/66

(52) U.S. Cl. CPC H01L 29/0634; H01L 21/0465; H01L 29/402; H01L 29/1608; H01L 29/7811; H01L 29/7813; H01L 29/66068

(57) ABSTRACT

In an entire intermediate region between an active region and an edge termination region, a p⁺-type region is provided between a p-type base region and a parallel pn layer. The p⁺-type region is formed concurrently with and in contact with p⁺-type regions for mitigating electric field near bottoms of gate trenches. The p⁺-type region has portions that face, respectively, n-type regions and p-type regions of a parallel pn layer in a depth direction Z and at the portions, has protrusions that protrude toward the parallel pn layer. N-type current spreading regions extend in the entire intermediate region from the active region and are between the p⁺-type region and the parallel pn layer, positioned between protrusions of the p⁺-type region. The impurity concentration of the n-type current spreading regions in the gate region is higher than that of those in other regions. Thus, avalanche capability may be enhanced.

### CROSS REFERENCE TO RELATED APPLICATIONS

This is a continuation application of International Application PCT/JP2021/042465 filed on Nov. 18, 2021 which claims priority from a Japanese Patent Application No. 2020-191731 filed on Nov. 18, 2020, the contents of which are incorporated herein by reference.

### BACKGROUND OF THE INVENTION

### 1. Field of the Invention

Embodiments of the invention relate to a silicon carbide semiconductor device.

### 2. Description of the Related Art

Semiconductor devices with a super junction (SJ) structure having a drift layer that is a parallel pn layer in which n-type regions and p-type regions are disposed alternating one another repeatedly in a direction parallel to a substrate main surface are conventionally known. As a method of forming the parallel pn layer, a trench-embedding epitaxial technique is known in which trenches (hereinafter, SJ trenches) are formed in an n-type epitaxial layer deposited to have a predetermined thickness, portions that are to form the n-type regions of the parallel pn layer are left while the SJ trenches are embedded with a p-type epitaxial layer to thereby form the p-type regions of the parallel pn layer.

In an instance in which the trench-embedding epitaxial technique is employed using silicon carbide (SiC) as a semiconductor material, a main surface of a semiconductor substrate (semiconductor chip) is a (0001) plane, i.e., a so-called Si-face, and the SJ trenches are formed in a striped pattern extending parallel to <11-20> of the epitaxial layers configuring the semiconductor substrate. The n-type regions and the p-type regions configuring the parallel pn layer extend linearly, parallel to <11-20> along which the SJ trenches extend, the n-type regions and the p-type regions reaching an outer side (end of the semiconductor substrate (chip end) side) of a voltage withstanding structure, from an active region of a center (chip center) of the semiconductor substrate.

FIG. 30 is a cross-sectional view of a structure of a conventional silicon carbide semiconductor device. FIGS. 31 and 33 are enlarged views of an intermediate region depicted in FIG. 30. FIG. 32 is an enlarged view of an area encompassed by a rectangular frame BB in FIG. 31. In FIG. 33, a region ion-implanted with an n-type impurity to form n-type current spreading regions 103 in an n⁻-type epitaxial layer 143 is indicated with hatching. In FIG. 33, to clarify an end position of the n-type current spreading regions 103, only contours of p⁺-type regions 111, 112, 113 formed by ion implantation in the n⁻-type epitaxial layer 143 are depicted.

A conventional silicon carbide semiconductor device 150 depicted in FIG. 30 is a vertical metal oxide semiconductor field effect transistor (MOSFET) having insulated gates with a 3-layer structure including a metal, an oxide, and a semiconductor, the vertical MOSFET having a SJ structure with a general trench gate structure in an active region 110 of a semiconductor substrate (semiconductor chip) 140 containing silicon carbide. The semiconductor substrate 140 is formed by stacking epitaxial layers 142, 143, 144 sequentially on an n⁺-type starting substrate 141 that contains silicon carbide.

The semiconductor substrate 140 has a main surface with the p-type epitaxial layer 144, assumed to be a front surface, and a main surface with the n⁺-type starting substrate 141 constituting an n⁺-type drain region 101, assumed to be a back surface. The epitaxial layer 142 is a drift layer 102 constituting a drift region and includes a parallel pn layer 160. The parallel pn layer 160 is formed by the trench-embedding epitaxial technique and is the SJ structure in which n-type regions 161 and p-type regions 162 are disposed alternating one another repeatedly in a first direction X that is parallel to the front surface of the semiconductor substrate 140. Reference character 102a is a portion of the drift layer 102, excluding the SJ structure.

The active region 110 is provided in a center (chip center) of the semiconductor substrate 140. In the active region 110, the n-type current spreading regions 103 constituting a current spreading layer (CSL) that reduces carrier spreading resistance, and the p⁺-type regions 111, 112 that mitigate electric field applied to bottoms of gate trenches 107 are each selectively provided in the n⁻ -type epitaxial layer 143. The n-type current spreading regions 103 and the p⁺-type regions 111, 112 are diffused regions formed by ion implantation.

A periphery of the active region 110 is surrounded by an edge termination region 130 with an intermediate region 120 intervening therebetween. In the edge termination region 130, a voltage withstanding structure such as a junction termination extension (JTE) structure 132 is disposed. FIG. 30 depicts multiple p-type regions of the JTE structure 132 as a single p--type region 133. A portion of the p-type epitaxial layer 144 in the edge termination region 130 is removed by etching, thereby forming a drop 131 at the front surface of the semiconductor substrate 140.

With the drop 131 as a boundary, the front surface of the semiconductor substrate 140 has a portion (hereinafter, second surface portion) 140b that is in the edge termination region 130 and recessed toward the n⁺-type drain region 101 as compared to a portion (hereinafter, first surface portion) 140a on the active region 110 side of the boundary. The front surface of the semiconductor substrate 140 further has a portion (mesa edge of the drop 131, hereinafter, third surface portion) 140c that connects the first surface portion 140a and the second surface portion 140b, and that separates elements of the edge termination region 130 and the elements of the active region 110 and of the intermediate region 120, which is between the active region 110 and the edge termination region 130.

In the edge termination region 130, the n⁻-type epitaxial layer 143 is exposed at the second surface portion 140b of the front surface of the semiconductor substrate 140. The p-type regions (the p⁻-type region 133) that configure the JTE structure 132 are selectively provided in surface regions of the n-type epitaxial layer 143, at the second surface portion 140b of the front surface of the semiconductor substrate 140. The p-type regions configuring the JTE structure 132 are diffused regions formed by ion implantation and are electrically connected to a p-type base region 104 by the p⁺-type region 113.

The p-type base region 104 is a portion of the p-type epitaxial layer 144, that remains after formation of the drop 131. The p-type base region 104 extends outward (toward the chip end) from the active region 110 and reaches the third surface portion 140c of the front surface of the semiconductor substrate 140, the p-type base region 104 being provided in an entire area of the intermediate region 120. The p⁺-type region 113 is a diffused region formed in the intermediate region 120 by ion implantation concurrently with p⁺-type regions 112 in the n⁻-type epitaxial layer 143, the p⁺-type region 113 being provided between the parallel pn layer 160 and the p-type base region 104 and surrounding the periphery of the active region 110.

The p⁺-type region 113 is adjacent to the p-type base region 104 and the n-type regions 161 and the p-type regions 162 of the parallel pn layer 160 in a depth direction Z. The p⁺-type region 113 extends inwardly (toward the chip center), reaches the active region 110, and is in contact with the n-type current spreading regions 103 and the p⁺-type regions 111, 112. The p⁺-type region 113 extends having a uniform thickness across an entire area of the intermediate region 120 and reaches the third surface portion 140c of the front surface of the semiconductor substrate 140 (FIG. 30). A uniform thickness means a thickness that is constant, within a range that includes an allowable error due to process variation.

A source electrode 115 extends from the active region 110 into an inner portion (hereinafter, peripheral contact region) 121 of the intermediate region 120, and in the inner portion (peripheral contact region) 121, a contact (electrical contact, hereinafter, peripheral contact) 121a between the source electrode 115 and a p⁺-type peripheral contact region 121b is formed. Minority carriers (holes) in the drift layer 102 in the edge termination region 130 when the MOSFET is off are discharged through the p-type base region 104 and the peripheral contact 121a to the source electrode 115.

The peripheral contact region 121 is an area between the active region 110 and an inner peripheral end of a gate runner (not depicted) disposed in a later-described gate region 122. The n-type current spreading regions 103 extend in an entire area of the peripheral contact region 121 from the active region 110. The n-type current spreading regions 103 are formed so as to overlap a p-type region 113, at a same depth as that of the p⁺-type region 113 or deeper and closer to the n⁺-type drain region 101 than is the p-type region 113, the n-type current spreading regions 103 existing with an ultrathin thickness between the p⁺-type region 113 and the n-type regions 161 of the parallel pn layer 160 (FIG. 33).

In an outer portion (hereinafter, gate region) 122 of the intermediate region 120, a gate runner 122a constituted by a polysilicon (poly-Si) layer is provided on a field oxide film 136. In the gate region 122, contacts (electrical contacts) between the gate runner 122a and gate electrodes 109 that extend from the active region 110 are formed. Reference numerals 114, 117, and 135 are an interlayer insulating film, a drain electrode, and a passivation film, respectively. In FIGS. 31 to 33, the gate runner 122a and the field oxide film 136 are not depicted.

As a conventional SJ structure semiconductor device, a device has been proposed in which in an area closer to the chip end than is the active region, a p-type RESURF region is selectively provided only in surface regions of the n-type regions of the parallel pn layer so as not to be in the p-type regions of the parallel pn layer (for example, refer to Japanese Laid-Open Patent Publication No. 2010-040973). In Japanese Laid-Open Patent Publication No. 2010-040973, the p-type regions of the parallel pn layer and the p-type RESURF regions overlap one another, whereby increases in the impurity concentration of the p-type regions of the parallel pn layer are suppressed and shifting of depletion conditions due to the overlap is avoided.

Further, as another conventional SJ structure semiconductor device, a device has been proposed in which in a surface region of an end (side surface) of a semiconductor substrate, an n-type surface region of a predetermined dose amount is formed along a slope of an end of the semiconductor substrate (for example, refer to Japanese Laid-Open Patent Publication No. 2007-208075). In Japanese Laid-Open Patent Publication No. 2007-208075, due to the n-type surface region of the end of the semiconductor substrate, spreading of a depletion layer at the end of the semiconductor substrate is suppressed and the occurrence of avalanche breakdown closer to the chip end than is the active region is suppressed so that the withstand voltage is determined by the critical electric field strength of an interface between a drain region and a drift layer in the active region and not the end of the semiconductor substrate.

### SUMMARY OF THE INVENTION

According to an embodiment of the present invention, a silicon carbide semiconductor device includes: a semiconductor substrate containing silicon carbide, the semiconductor substrate having a first main surface and a second main surface that are opposite to each other; a parallel pn layer in which a plurality of first-conductivity-type regions and a plurality of second-conductivity-type regions alternate with one another repeatedly in a first direction that is parallel to the first main surface of the semiconductor substrate, the parallel pn layer being provided in the semiconductor substrate, spanning an active region and a termination region that surrounds a periphery of the active region; a first surface portion of the first main surface of the semiconductor substrate, the first surface portion excluding a portion of the first main surface in the termination region; a second surface portion of the first main surface of the semiconductor substrate, the second surface portion being the portion of the first main surface in the termination region; a stepped portion provided on the first main surface of the semiconductor substrate, between the first surface portion and the second surface portion, at which the second surface portion is recessed in a depth direction with respect to the first surface portion toward the second main surface of the semiconductor substrate; a first semiconductor region of a second conductivity type, provided between the first surface portion of the semiconductor substrate and the parallel pn layer, the first semiconductor region extending from the active region to an intermediate region between the active region and the termination region, and reaching the stepped portion; a plurality of second semiconductor regions of a first conductivity type, provided in the active region, between and in contact with the first semiconductor region and the parallel pn layer; a plurality of third semiconductor regions of the first conductivity type, selectively provided in the active region, between the first surface portion of the semiconductor substrate and the first semiconductor region; a plurality of trenches that penetrate through the plurality of third semiconductor regions and the first semiconductor region, and reach the plurality of second semiconductor regions; a gate insulating film provided in each of the plurality of trenches; a plurality of gate electrodes provided on the gate insulating film in respective ones of the plurality of trenches; a plurality of first high-concentration regions of the second conductivity type, provided between bottoms of the plurality of trenches and the parallel pn layer, each of the plurality of first high-concentration regions facing the bottom of a respective one of the plurality of trenches in the depth direction and having an impurity concentration that is higher than an impurity concentration of the first semiconductor region; a plurality of second high-concentration regions of the second conductivity type, provided between the first semiconductor region and the parallel pn layer in the active region so as to be in contact with the first semiconductor region and apart from the plurality of trenches and the plurality of first high-concentration regions, each of the plurality of second high-concentration regions having an impurity concentration that is higher than the impurity concentration of the first semiconductor region; a third high-concentration region of the second conductivity type, provided between the first semiconductor region and the parallel pn layer in the intermediate region, the third high-concentration region being in contact with the first semiconductor region and electrically connected to both the first high-concentration regions and the second high-concentration regions, the third high-concentration region surrounding the periphery of the active region and having an impurity concentration that is higher than the impurity concentration of the first semiconductor region; a fourth semiconductor region of the second conductivity type, selectively provided between the second surface portion of the semiconductor substrate and the parallel pn layer, the fourth semiconductor region surrounding the periphery of the active region with the intermediate region intervening therebetween, the fourth semiconductor region being electrically connected to the first semiconductor region via the third high-concentration region and configuring the voltage withstanding structure; a first electrode electrically connected to the plurality of third semiconductor regions and the first semiconductor region; and a second electrode provided on the second main surface of the semiconductor substrate. The intermediate region has a first intermediate region in which an electrical contact between the first electrode and the first semiconductor region is formed, and a second intermediate region that is between the first intermediate region and the termination region. The third high-concentration region has a first portion that faces at least one of the plurality of first-conductivity-type regions of the parallel pn layer, and a second portion that faces at least one of the plurality of second-conductivity-type regions of the parallel pn layer, the first and second portions respectively having a first protrusion and a second protrusion, each protruding in the depth direction toward the parallel pn layer. The plurality of second semiconductor regions extend from the active region to the intermediate region and reach the stepped portion. Each of the plurality of second semiconductor regions is between the third high-concentration region and the parallel pn layer, positioned between a respective adjacent pair of protrusions of the plurality of protrusions of the third high-concentration region, and is adjacent to a corresponding one of the plurality of first-conductivity-type regions of the parallel pn layer in the depth direction. Among the plurality of second semiconductor regions, ones in the second intermediate region have an impurity concentration that is higher than an impurity concentration of others outside the second intermediate region.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting a layout when a silicon carbide semiconductor device according to a first embodiment is viewed from a front surface of a semiconductor substrate thereof.

FIG. 2 is a cross-sectional view of a structure along cutting line A-A′ in FIG. 1.

FIG. 3 is an enlarged view of a portion depicted in FIG. 2.

FIG. 4A is an enlarged plan view of a portion depicted in FIG. 2.

FIG. 4B is an enlarged view of a portion depicted in FIG. 2.

FIG. 5 is an enlarged view of a portion within a rectangular frame B depicted in FIG. 4B.

FIG. 6 is an enlarged view of a portion depicted in FIG. 2.

FIG. 7 is a cross-sectional view depicting a state of the silicon carbide semiconductor device according to the first embodiment during manufacture.

FIG. 8 is a cross-sectional view depicting a state of the silicon carbide semiconductor device according to the first embodiment during manufacture.

FIG. 9 is a cross-sectional view depicting a state of the silicon carbide semiconductor device according to the first embodiment during manufacture.

FIG. 10 is a cross-sectional view depicting a state of the silicon carbide semiconductor device according to the first embodiment during manufacture.

FIG. 11 is a cross-sectional view depicting a state of the silicon carbide semiconductor device according to the first embodiment during manufacture.

FIG. 12 is a cross-sectional view depicting a state of the silicon carbide semiconductor device according to the first embodiment during manufacture.

FIG. 13 is a cross-sectional view depicting a state of the silicon carbide semiconductor device according to the first embodiment during manufacture.

FIG. 14 is a plan view depicting a layout when a silicon carbide semiconductor device according to a second embodiment is viewed from the front side of the semiconductor substrate.

FIG. 15 is a plan view depicting another layout when the silicon carbide semiconductor device according to the second embodiment is viewed from the front side of the semiconductor substrate.

FIG. 16 is a distribution diagram depicting results of simulating electric field strength in a depth direction for a first example.

FIG. 17 is a distribution diagram depicting results of simulating electric field strength in the depth direction for a conventional example.

FIG. 18 is a distribution diagram depicting results of simulating electric field strength in a first direction for the first example.

FIG. 19 is an enlarged view of an area within a rectangular frame C1 depicted in FIG. 18.

FIG. 20 is an enlarged view of an area within a rectangular frame C2 depicted in FIG. 18.

FIG. 21 is a distribution diagram depicting results of simulating electric field strength in the first direction for the conventional example.

FIG. 22 is a distribution diagram depicting results of simulating carrier density during avalanche breakdown in a second example.

FIG. 23 is a distribution diagram depicting results of simulating carrier density during avalanche breakdown in the conventional example.

FIG. 24 is a distribution diagram depicting results of simulation of hole current amount during avalanche breakdown in the second example.

FIG. 25 is a distribution diagram depicting results of simulation of the hole current amount during avalanche breakdown in the conventional example.

FIG. 26 is a distribution diagram depicting results of simulation of hole current density near a peripheral contact in the second example.

FIG. 27 is a distribution diagram depicting impurity concentration near peripheral contacts in the second example.

FIG. 28 is a distribution diagram depicting the impurity concentration near peripheral contacts in the conventional example.

FIG. 29 is a characteristics diagram depicting results of simulation of voltage-current characteristics in the second example.

FIG. 30 is a cross-sectional view of a structure of a conventional silicon carbide semiconductor device.

FIG. 31 is an enlarged view of an intermediate region depicted in FIG. 30.

FIG. 32 is an enlarged view of an area encompassed by a rectangular frame BB in FIG. 31.

FIG. 33 is an enlarged view of the intermediate region depicted in FIG. 30.

### DETAILED DESCRIPTION OF THE INVENTION

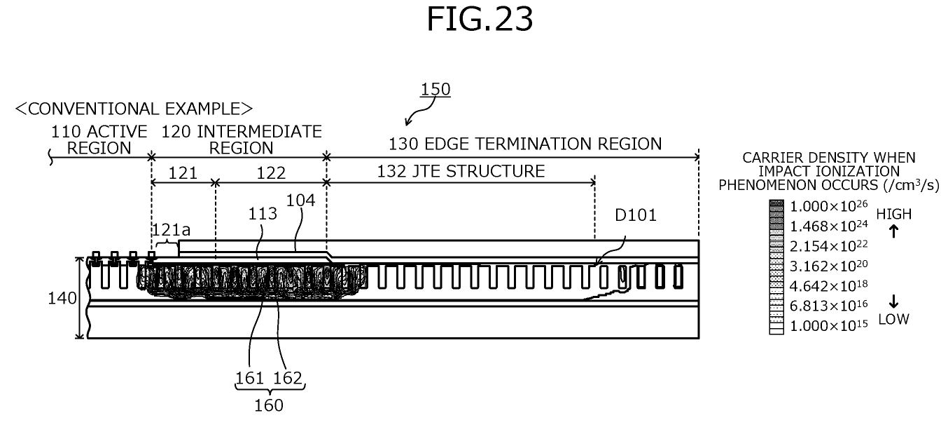

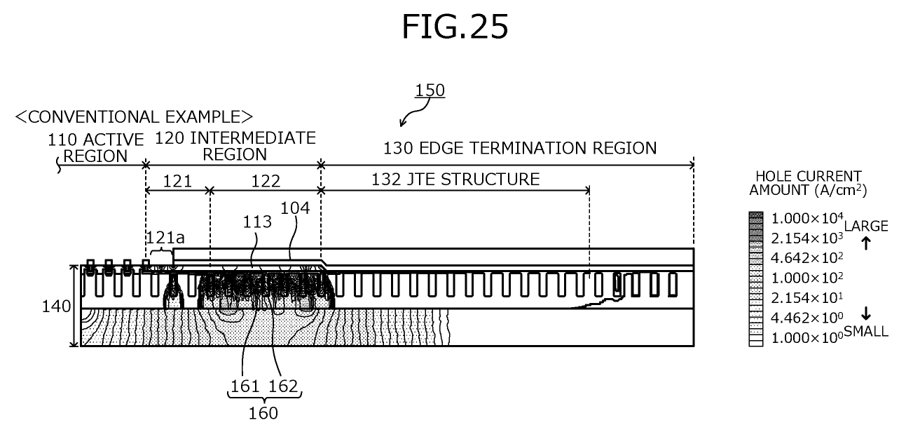

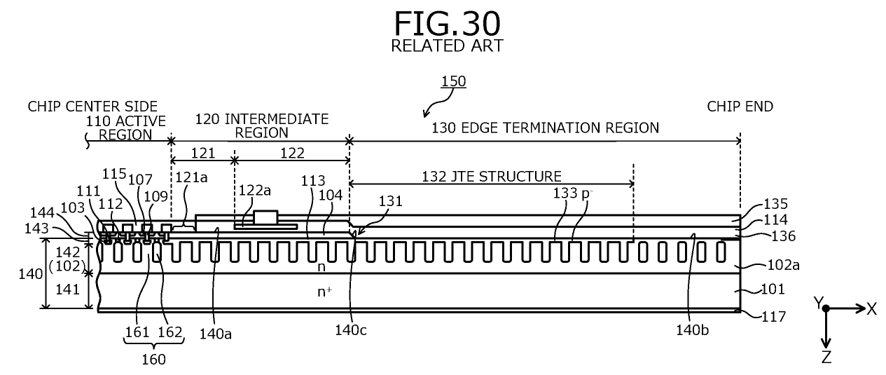

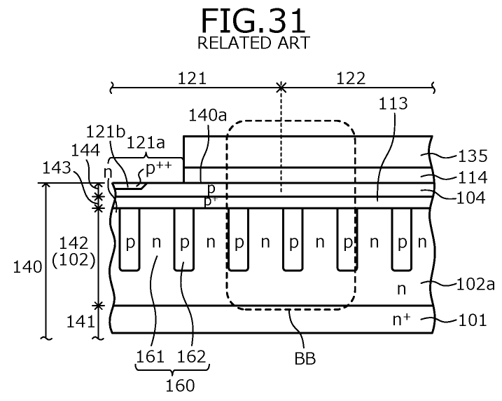

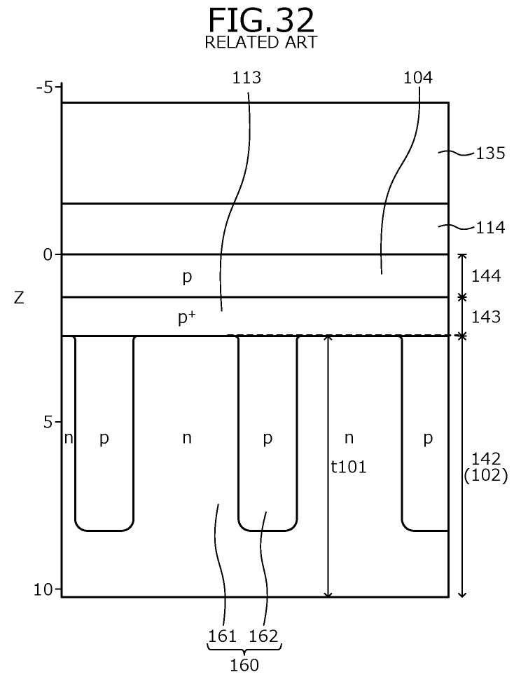

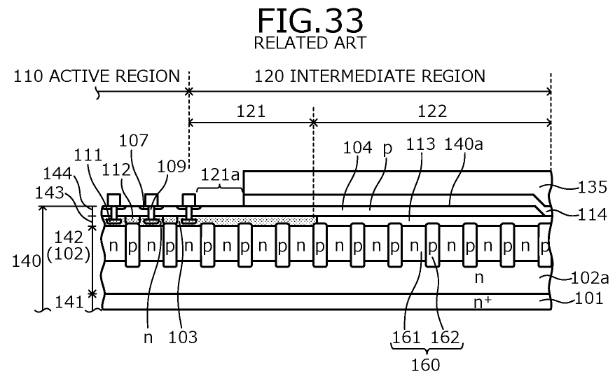

First, problems associated with the conventional techniques are discussed. As a result of intensive research by the inventor, the following was found with regard to the conventional silicon carbide semiconductor device 150 (refer to FIGS. 30 to 33). During the off state, an impact ionization phenomenon occurs in the parallel pn layer 160 of the intermediate region 120 and avalanche breakdown occurs (refer to FIG. 23). As a result, when hole current (hereinafter, avalanche current), which increased sharply, is discharged from the p⁺-type peripheral contact region 121b to the source electrode 115 via the p⁺-type region 113 of the intermediate region 120, concentration occurs in the p⁺-type region 113 and the peripheral contact 121a (refer to FIG. 25).

Avalanche current concentrates in the peripheral contact 121a and the p⁺-type region 113 of the intermediate region 120, whereby the silicon carbide semiconductor device 150 is destroyed in an area closer to the chip end than is the active region 110. Therefore, the avalanche capability in the intermediate region 120 and the edge termination region 130 becomes smaller than the avalanche capability in the active region 110. As a result, destruction due to surge current or surge voltage depends on the capability of the intermediate region 120 and the edge termination region 130, and the current capability of the active region 110 cannot be fully realized.

Embodiments of a silicon carbide semiconductor device according to the present invention are described in detail with reference to the accompanying drawings. In the present description and accompanying drawings, layers and regions prefixed with n or p mean that majority carriers are electrons or holes. Additionally, + or - appended to n or p means that the impurity concentration is higher or lower, respectively, than layers and regions without + or -, and represents one example. In the description of the embodiments below and the accompanying drawings, main portions that are identical are given the same reference numerals and are not repeatedly described. Further, in the present description, when Miller indices are described, “-” means a bar added to an index immediately after the “-”, and a negative index is expressed by prefixing “-” to the index.

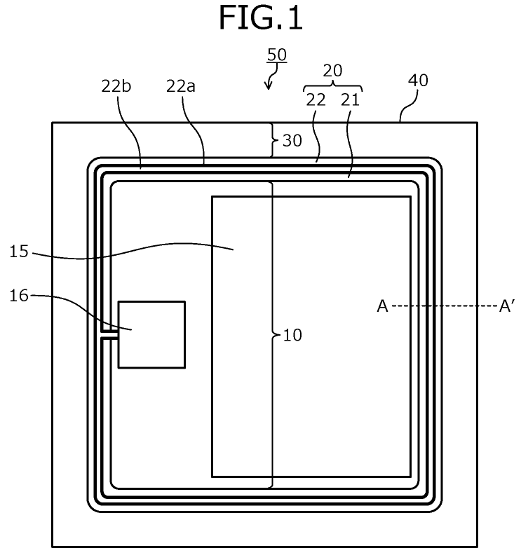

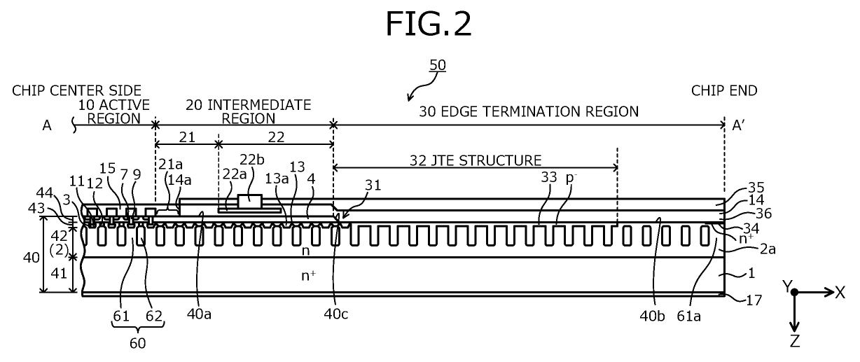

A structure of a silicon carbide semiconductor device according to a first embodiment is described. FIG. 1 is a plan view depicting a layout when the silicon carbide semiconductor device according to the first embodiment is viewed from a front surface (first main surface) of a semiconductor substrate thereof. In FIG. 1, an inner periphery of a solid-lined rectangular frame indicating a gate runner 22a is a border between a peripheral contact region (first intermediate region) 21 and a gate region (second intermediate region) 22. FIG. 2 is a cross-sectional view of the structure along cutting line A-A′ in FIG. 1. FIG. 2 depicts a portion from near a border between an active region 10 and an intermediate region 20 to an end (chip end) of a semiconductor substrate 40.

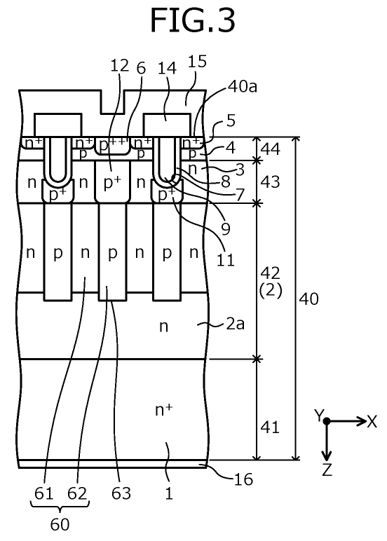

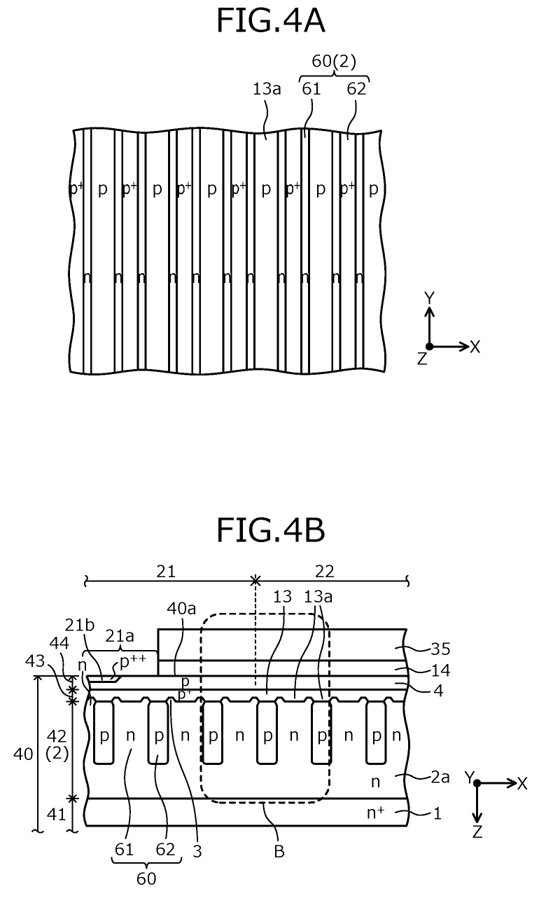

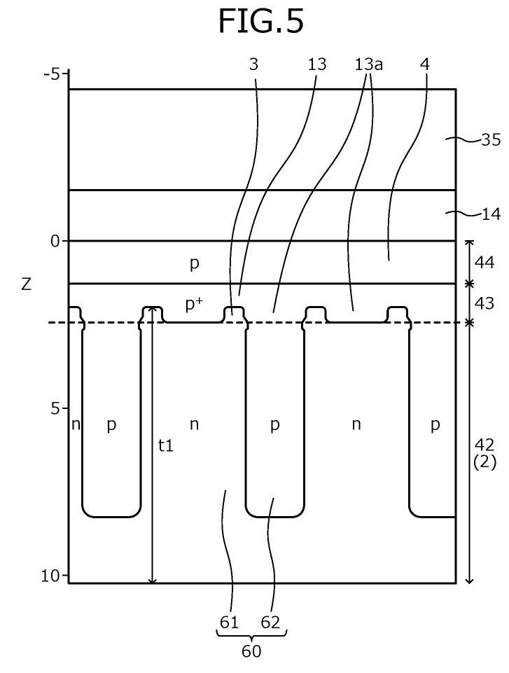

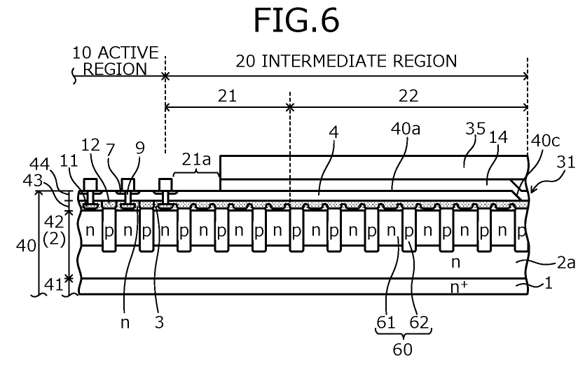

FIGS. 3 and 6 are enlarged views of a portion depicted in FIG. 2. FIGS. 4A and 4B are enlarged views of a portion depicted in FIG. 2. FIG. 5 is an enlarged view of a portion within a rectangular frame B depicted in FIG. 4B. While FIG. 3 depicts a single unit cell among unit cells (component units of device element) disposed in the active region 10, all of the unit cell disposed in the active region 10 have the same structure. While FIGS. 4A and 4B depict a portion of a p⁺-type region 13 of the intermediate region 20a, the p⁺-type region 13 is configured similarly across an entire area of the intermediate region 20.

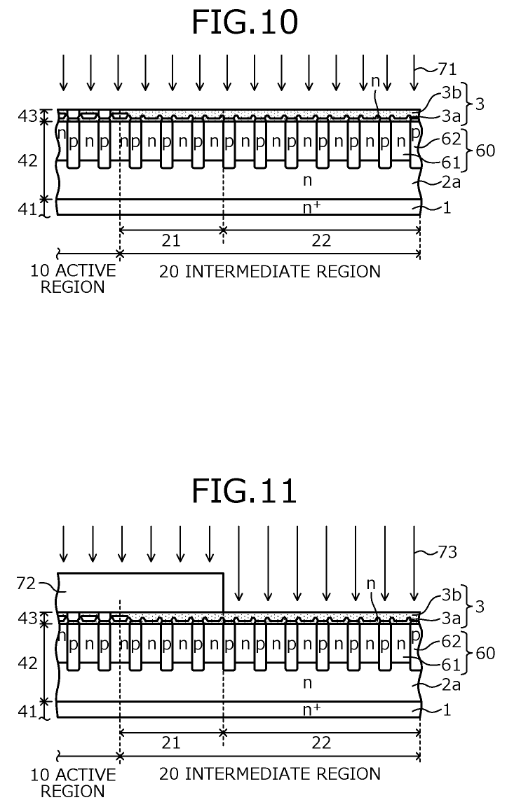

FIG. 4A is a plan view depicting a layout when the p⁺-type region 13 of the intermediate region 20 is viewed from the front surface of the semiconductor substrate 40; FIG. 4B is a cross-sectional view of the p⁺-type region 13 of the intermediate region 20. The planar layout (FIG. 4A) and cross-sectional structure (FIG. 4B) of the p⁺-type region 13 are the same across the entire area of the intermediate region 20. In FIG. 6, regions ion-implanted with an n-type impurity to form n-type current spreading regions 3 in an n⁻-type epitaxial layer 43 are indicated by hatching (similarly in FIGS. 10 to 13).

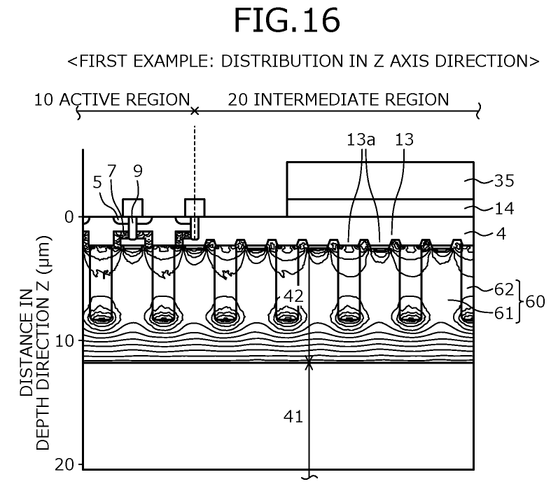

In FIG. 6, to clarify end positions of the n-type current spreading regions 3 indicated by hatching, of the n-type current spreading regions 3 and p⁺-type regions 11 to 13 formed by ion implantation in the n⁻-type epitaxial layer 43, only contours of the p⁺-type regions 11 to 13 are depicted and “p⁺” indicating the conductivity type is not depicted (similarly in FIGS. 10 to 13). In FIG. 4A to 6, the gate runner 22a, a gate wiring layer 22b, and a field oxide film 36 are not depicted (similarly in FIGS. 16 to 18, 22, 24, 27).

A silicon carbide semiconductor device 50 according to the first embodiment depicted in FIGS. 1, 2 has a semiconductor substrate (semiconductor chip) 40 that contains silicon carbide (SiC) and has the active region 10, the intermediate region 20, and an edge termination region 30, and is a vertical MOSFET with a trench gate structure and a SJ structure that spans the active region 10 and the edge termination region 30 and has a parallel pn layer 60 as a drift layer 2. As depicted in FIG. 1, the active region 10 is disposed in a center (chip center) of the semiconductor substrate 40. The active region 10 is a region through which a main current flows when the MOSFET is in an ON state.

The intermediate region 20 is a region between the active region 10 and the edge termination region 30, surrounds a periphery of the active region 10 and is in contact with the active region 10. The edge termination region 30 is a region between the intermediate region 20 and the end of the semiconductor substrate 40, the edge termination region 30 surrounding the periphery of the active region 10 with the intermediate region 20 intervening therebetween. The edge termination region 30 has a function of mitigating electric field of a front side of the semiconductor substrate 40 and sustaining a breakdown voltage of the drift layer 2 in the active region 10 and the intermediate region 20. The breakdown voltage is a voltage limit at which no excessive increase in leakage current, erroneous operation nor destruction of the device element occurs.

In the edge termination region 30, a voltage withstanding structure such as a junction termination extension (JTE) structure 32, a field limiting ring (FLR), etc. is disposed in a front side of the semiconductor substrate 40. Here, an instance in which in the edge termination region 30, the JTE structure 32 (refer to FIG. 2) is disposed in the front side of the semiconductor substrate 40 is described. Due to the voltage withstanding structure, a concentration of electric field closer to the chip end than is the active region 10 is mitigated and destruction of the device element does not occur when voltage is applied up to a predetermined voltage.

As depicted in FIG. 2, in the active region 10, the trench gate structure is provided in the front side of the semiconductor substrate 40. The trench gate structure is configured by a p-type base region (first semiconductor region) 4, n⁺-type source regions (third semiconductor regions) 5, p⁺⁺-type contact regions 6, gate trenches 7, a gate insulating film 8, and gate electrodes 9. In the semiconductor substrate 40, epitaxial layers 42, 43, 44 constituting the drift layer 2, the n-type current spreading regions (second semiconductor regions) 3, and the p-type base region 4, respectively, are sequentially stacked on a front surface of an n⁺-type starting substrate 41 that contains silicon carbide.

The semiconductor substrate 40 has, as the front surface, a main surface having the p-type epitaxial layer 44 and, as a back surface (second main surface), a main surface having the n⁺-type starting substrate 41 (back surface of the n⁺-type starting substrate 41). Crystal orientation of the front surface of the semiconductor substrate 40, for example, is a (0001) plane. The n⁺-type starting substrate 41 constitutes an n⁺-type drain region 1. The gate trenches 7 penetrate through the p-type epitaxial layer 44 from the front surface of the semiconductor substrate 40 in the depth direction Z, penetrate into the n⁻-type epitaxial layer 43, and extend in a striped pattern, in a direction (here, later-described second direction Y) parallel to the front surface of the semiconductor substrate 40.

A portion of the p-type epitaxial layer 44 in the edge termination region 30 is removed by etching, thereby forming a drop (stepped portion) 31 at the front surface of the semiconductor substrate 40. With the drop 31 as a boundary, the front surface of the semiconductor substrate 40 has a portion (second surface portion) 40b that is in the edge termination region 30 and recessed toward the n⁺-type drain region 1 as compared to a portion (first surface portion) 40a that is on the active region 10 side of the boundary. The front surface of the semiconductor substrate 40 has a portion (third surface portion) 40c that connects the first surface portion 40a and the second surface portion 40b, and the third surface portion 40c separates elements of the edge termination region 30 from the elements of the active region 10 and of the intermediate region 20.

The gate electrodes 9 are provided in the gate trenches 7, via the gate insulating film 8. The p-type base region 4, the n⁺-type source regions 5, and the p⁺⁺-type contact regions 6 are selectively provided between adjacent gate trenches of the gate trenches 7 and, for example, extend linearly in the second direction Y in which the gate trenches 7 extend. The p-type base region 4 is a portion of the p-type epitaxial layer 44 left after the drop 31 of the front surface of the semiconductor substrate 40 is formed, excluding the n⁺-type source regions 5 and the p⁺⁺-type contact regions 6.

The p-type base region 4 extends outward (toward the chip end) from the active region 10 and reaches the third surface portion 40c of the front surface of the semiconductor substrate 40 so as to be provided in the entire area of the intermediate region 20. The n⁺-type source regions 5 and the p⁺⁺-type contact regions 6 are provided between the front surface of the semiconductor substrate 40 and the p-type base region 4, and are in contact with the p-type base region 4. Further, the n⁺-type source regions 5 and the p⁺⁺-type contact regions 6 are exposed at the first surface portion 40a of the front surface of the semiconductor substrate 40 and are in contact with a source electrode (first electrode) 15 via contact holes in an interlayer insulating film 14.

The n⁺-type source regions 5 face the gate electrodes 9 across the gate insulating film 8 at side walls of the gate trenches 7. The p⁺⁺-type contact regions 6 are disposed at positions further from the gate trenches 7 than are the n⁺-type source regions 5. The epitaxial layer 42 is provided between the p-type base region 4 and the back surface of the semiconductor substrate 40. The epitaxial layer 42 is the drift layer 2 that constitutes a drift region and includes the parallel pn layer 60. A portion 2a of the drift layer 2 between the parallel pn layer 60 and the n⁺-type starting substrate 41 may be a normal n-type drift region that is not a SJ structure.

The parallel pn layer 60 is an epitaxial layer of the SJ structure in which n-type regions (first-conductivity-type regions) 61 and p-type regions (second-conductivity-type regions) 62 are disposed alternating one another repeatedly in the first direction X, which is parallel to the front surface of the semiconductor substrate 40. In the parallel pn layer 60, for example, SJ trenches are formed in an n-type epitaxial layer that is formed by a single step (single session) of epitaxial growth using the trench-embedding epitaxial technique, the n-type epitaxial layer constitutes the n-type regions 61 and the SJ trenches penetrating through the n-type epitaxial layer in the depth direction Z, and a p-type epitaxial layer constitutes the p-type regions 62 embedded in the SJ trenches.

The n-type regions 61 and the p-type regions 62 of the parallel pn layer 60 extend linearly in the second direction Y that is parallel to the front surface of the semiconductor substrate 40 and orthogonal to the first direction X. The second direction Y, for example, corresponds to <11-20>. The n-type regions 61 and the p-type regions 62 adjacent thereto are approximately charge balanced. An outermost n-type region 61a is disposed along the chip end, in an outermost periphery of the parallel pn layer 60. The outermost n-type region 61a of the parallel pn layer 60 surrounds a periphery of a center-side portion of the semiconductor substrate 40 and connects all the n-type regions 61 of the parallel pn layer 60.

In the active region 10, the n-type current spreading regions 3 and p⁺-type regions (first, second high-concentration regions) 11, 12 are selectively provided between the p-type base region 4 and the drift layer 2. The n-type current spreading regions 3 and the p⁺-type regions 11, 12 are diffused regions formed by ion-implantation in the n⁻-type epitaxial layer 43. Further, between the p-type base region 4 and the drift layer 2, the n-type current spreading regions 3 extend outwardly from the active region 10, reach the third surface portion 40c of the front surface of the semiconductor substrate 40, and are provided in the entire area of the intermediate region 20 (refer to FIG. 6).

The n-type current spreading regions 3 constitute a so-called current spreading layer (CSL) that reduces minority carrier resistance. In the active region 10, the n-type current spreading regions 3 are disposed, respectively, between adjacent gate trenches 7 among the gate trenches 7, so as to be in contact with the gate trenches 7. The n-type current spreading regions 3 reach deep positions closer to the n⁺-type drain region 1 than are the gate trenches 7. In the active region 10, each of the n-type current spreading regions 3 is between a respective one of the gate trenches 7, a respective p⁺-type region 11, and a respective p⁺-type region 12, while in the depth direction Z, is adjacent to the p-type base region 4 and a respective one of the n-type regions 61 of the parallel pn layer 60.

The n-type current spreading regions 3 extend outward from the active region 10 and reach an area beneath the third surface portion 40c of the front surface of the semiconductor substrate 40. As a result, the n-type current spreading regions 3 are provided in an entire area of the intermediate region 20 and the active region 10. In the intermediate region 20, the n-type current spreading regions 3 are provided between the p⁺-type region 13 and the parallel pn layer 60, and as described hereinafter, are between protrusions (first and second protrusion) 13a of the p⁺-type region (third high-concentration region) 13 while being adjacent to the p⁺-type region 13 and the n-type regions 61 of the parallel pn layer 60 in the depth direction Z.

The n-type current spreading regions 3 may reach deep positions closer to the n⁺-type drain region 1 than are the p⁺-type regions 11, 12 in the active region 10 and the protrusions 13a of the p⁺-type region 13 in the intermediate region 20, and may be between the p⁺-type regions 11 to 13 and the n-type regions 61 of the parallel pn layer 60. Of the n-type current spreading regions 3 indicated by hatching in FIG. 6, portions overlapping the p⁺-type regions 11 to 13 are portions constituting the p⁺-type regions 11 to 13 formed by ion implantation of a p-type impurity to form the p⁺-type regions 11 to 13 in the n⁻-type epitaxial layer 43.

The n-type current spreading regions 3 in a later-described gate region 22 have an impurity concentration that is higher than that of the n-type current spreading regions 3 in other regions (the active region 10 and the later-described peripheral contact region 21) and preferably, in the gate region 22, the impurity concentration may be, for example, in a range of about 1.3 times to 1.7 times higher. The higher is the impurity concentration of the n-type current spreading regions 3 in the gate region 22, the greater the effective thickness of the drift region may be increased in the intermediate region 20 as compared to the active region 10. As a result, the electric field strength of the intermediate region 20 may be relatively decreased.

The p⁺-type regions 11 and 12 have a function of mitigating electric field applied to bottoms of the gate trenches 7. The p⁺-type regions 11 face the bottoms of the gate trenches 7 and the n-type regions 61 of the parallel pn layer 60 in the depth direction . The p⁺-type regions 11 are disposed from the front surface of the semiconductor substrate 40 to deep positions closer to the n⁺-type drain region 1 than is an interface between the p-type base region 4 and the n-type current spreading regions 3, the p⁺-type regions 11 being disposed apart from the p-type base region 4 and the p-type regions 62 of the parallel pn layer 60. The p⁺-type regions 11 may be in contact with the n-type regions 61 of the parallel pn layer 60 in the depth direction Z.

Between the gate trenches 7 that are adjacent to one another, the p⁺-type regions 12 are provided apart from the p⁺-type regions 11 and the gate trenches 7. The p⁺-type regions 12 are in contact with the p-type base region 4 and the p-type regions 62 of the parallel pn layer 60 in the depth direction Z. The interlayer insulating film 14 covers an entire area of the front surface of the semiconductor substrate 40 excluding contact portions of the active region 10 and a later-described peripheral contact 21a. The contact portions of the active region 10 are ohmic contacts between the source electrode 15 and, the n⁺-type source regions 5 and the p⁺⁺-type contact regions 6.

The intermediate region 20 is a region up to the drop 31, the region being closer to the chip end than are ends of the n⁺-type source regions 5 in the second direction Y and closer to the chip end than is a center of an outermost gate trench that is outermost of the gate trenches 7 in the first direction X. In an inner portion (peripheral contact region) 21 of the intermediate region 20 (portion facing the chip center), the source electrode 15 extends from the active region 10, and the ohmic contact (electrical contact, hereinafter, peripheral contact) 21a between the source electrode 15 and the p⁺-type peripheral contact region 21b (in an instance in which the p⁺-type peripheral contact region 21b is omitted, the p-type base region 4) is provided.

The peripheral contact region 21 is a portion between the active region 10 and an inner peripheral end of the gate runner 22a disposed in the later-described gate region 22. The peripheral contact 21a is formed in a contact hole 14a that, in the depth direction Z, penetrates through a later described insulating layer (the interlayer insulating film 14, etc.) covering the front surface of the semiconductor substrate 40 in the intermediate region 20 and the edge termination region 30. The p⁺-type peripheral contact region 21b is selectively provided between the first surface portion 40a of the front surface of the semiconductor substrate 40 and the p-type base region 4, in the peripheral contact region 21.

When the MOSFET is off, minority carriers (holes) generated in the drift layer 2 in the edge termination region 30 are discharged to the source electrode 15 via the p-type base region 4 and the peripheral contact 21a. In the intermediate region 20 and the edge termination region 30, the front surface of the semiconductor substrate 40 (portion of the front surface of the semiconductor substrate 40 closer to the chip end than is the peripheral contact 21a) is covered by an insulating layer in which the field oxide film 36 and the interlayer insulating film 14 are sequentially stacked.

In a portion (gate region) 22 of the intermediate region 20, closer to the chip end than is the peripheral contact region 21, the gate runner 22a formed by a polysilicon (poly-Si) layer is provided on the field oxide film 36. The gate runner 22a is covered by the interlayer insulating film 14. On the gate runner 22a, the gate wiring layer 22b is provided via a contact hole of the interlayer insulating film 14. The gate runner 22a and the gate wiring layer 22b are electrically connected to a gate pad 16 (refer to FIG. 1).

The gate region 22 surrounds the periphery of the active region 10 with the peripheral contact region 21 intervening therebetween. In the gate region 22, the gate electrodes 9 extend from the active region 10, and contact portions (electrical contacts: not depicted) between the gate runner 22a and the gate electrodes 9 are provided. The gate runner 22a extends along an inner periphery of the gate region 22 and surrounds the periphery of the active region 10. The gate wiring layer 22b extends along the gate runner 22a and surrounds the periphery of the active region 10.

Further, spanning the entire area of the intermediate region 20, the p⁺-type region 13 is provided between the p-type base region 4 and the parallel pn layer 60 (the drift layer 2). The p⁺-type region 13 is a diffused region formed concurrently with the p⁺-type regions 11, 12 in the n⁻-type epitaxial layer 43 in the intermediate region 20 by ion implantation. The p⁺-type region 13 surrounds the periphery of the active region 10. The p⁺-type region 13 extends inward to reach the active region 10 and is in contact with and electrically connected to the p⁺-type regions 11, 12.

The p⁺-type region 13 extends outwardly to reach an area beneath the third surface portion 40c of the front surface of the semiconductor substrate 40 and is in contact with an innermost p-type region of the later-described JTE structure 32. An entire surface of the p⁺-type region 13 facing the p-type base region 4 is in contact with the p-type base region 4. Further, the p⁺-type region 13, at portions (first and second portions) thereof respectively facing the n-type regions 61 and the p-type regions 62 of the parallel pn layer 60 in the depth direction Z, has the protrusions (first and second protrusions) 13a that protrude toward the parallel pn layer 60. The thickness of the p⁺-type region 13 is thinner at portions between the protrusions 13a than at the portions with the protrusions 13a (refer to FIGS. 4B and 5).

The number of the protrusions 13a of the p⁺-type region 13 is equal to the number of the n-type regions 61 and the p-type regions 62 of the parallel pn layer 60 in the intermediate region 20, the protrusions 13a being provided apart from one another at a predetermined interval in the first direction X. The protrusions 13a of the p⁺-type region 13 extend in the second direction Y, which is the same direction in which the n-type regions 61 and the p-type regions 62 of the parallel pn layer 60 extend (refer to FIG. 4A). FIG. 4A depicts a layout of the n-type regions 61 and the p-type regions 62 of the parallel pn layer 60, and the protrusions 13a of the p⁺-type region 13, the protrusions 13a facing the n-type regions 61 of the parallel pn layer 60 in the depth direction Z.

Of the p⁺-type region 13, the protrusions 13a that face the n-type regions 61 in the depth direction Z are in contact with the n-type regions 61 or face the n-type regions 61 in the depth direction Z with the n-type current spreading regions 3 intervening therebetween. Of the p⁺-type region 13, the protrusions 13a that face the n-type regions 61 in the depth direction Z are disposed apart from the p-type regions 62. Of the p⁺-type region 13, the protrusions 13a that face the p-type regions 62 in the depth direction Z are in contact with the p-type regions 62. The n-type current spreading regions 3 are positioned between the protrusions 13a of the p⁺-type region 13 and are adjacent to the n-type regions 61 in the depth direction Z.

Due to the n-type current spreading regions 3 between the protrusions 13a of the p⁺-type region 13, the effective thickness (total thickness of the drift layer 2 and the n-type current spreading regions 3 between the protrusions 13a of the p⁺-type region 13) t1 (FIG. 5) of the drift region in the intermediate region 20 is thicker than an effective thickness t101 (FIG. 32) of the drift region (the drift layer 102) in the intermediate region 120 of the conventional structure. Therefore, compared to the conventional structure, the effective thickness t1 of the drift region in the intermediate region 20 approaches the effective thickness (total thickness of the drift layer 2 and the n-type current spreading regions 3) of the drift region in the active region 10.

As a result, in the parallel pn layer 60 at the front side of the semiconductor substrate 40, distribution of the electric field strength of the intermediate region 20 becomes the same as the distribution of the electric field strength of the active region 10 (refer to FIGS. 16, 18 to 20). As described above, the impurity concentration of the n-type current spreading regions 3 in the gate region 22 is set relatively high, whereby the electric field strength in the intermediate region 20 is relatively small and therefore, distribution of the electric field strength of the intermediate region 20 and distribution of the electric field strength of the active region 10 become substantially the same and the electric field strength of the active region 10 may be set to be greater than the electric field strength of the intermediate region 20.

In the edge termination region 30, the n⁻-type epitaxial layer 43 is exposed at the second surface portion 40b of the front surface of the semiconductor substrate 40. In the entire second surface portion 40b of the front surface of the semiconductor substrate 40, multiple p-type regions configuring the JTE structure 32 are selectively provided in the n⁻-type epitaxial layer 43. The JTE structure 32 is a structure in which the p-type regions of differing impurity concentrations are disposed adjacent to one another in concentric circles surrounding the periphery of the active region 10 so that the p-type regions are disposed apart from one another in descending order of impurity concentration in a direction from the chip center side to the chip end.

The p-type regions configuring the JTE structure 32 are diffused regions formed in the n⁻-type epitaxial layer 43 by ion implantation and are exposed at the second surface portion 40b of the front surface of the semiconductor substrate 40. Further, the p-type regions configuring the JTE structure 32 penetrate through the n⁻-type epitaxial layer 43 in the depth direction Z to reach the parallel pn layer 60 and be in contact with the n-type regions 61 and the p-type regions 62 of the parallel pn layer 60. The p-type base region 4 and the p⁺-type region 13 are exposed at the third surface portion 40c of the front surface of the semiconductor substrate 40.

The p-type regions configuring the JTE structure 32 are electrically connected to the p-type base region 4 by the p⁺-type region 13 near the third surface portion 40c of the front surface of the semiconductor substrate 40. In FIG. 2, the multiple p-type regions of the JTE structure 32 are depicted as a single p⁻-type region (fourth semiconductor region) 33. Exposure at the second and third surface portions 40b, 40c of the front surface of the semiconductor substrate 40 means being provided in surface regions at the second and third surface portions 40b, 40c of the front surface of the semiconductor substrate 40 and being in contact with the interlayer insulating film 14 on the second and third surface portions 40b, 40c of the front surface of the semiconductor substrate 40.

Further, in surface regions at the second surface portion 40b of the front surface of the semiconductor substrate 40, closer to the chip end than is the JTE structure 32, an n⁺-type stopper region 34 is selectively provided apart from the JTE structure 32. At the second surface portion 40b of the front surface of the semiconductor substrate 40, the n⁻-type epitaxial layer 43 is exposed between the JTE structure 32 and the n⁺-type stopper region 34. The n⁺-type stopper region 34 is exposed at the second surface portion 40b of the front surface of the semiconductor substrate 40 and the end of the semiconductor substrate 40. The n⁺-type stopper region 34 may face the parallel pn layer 60 in the depth direction Z.

The second and third surface portions 40b, 40c of the front surface of the semiconductor substrate 40, as described above, is covered by an insulating layer in which the field oxide film and the interlayer insulating film 14 are sequentially stacked. A passivation film 35 covers the entire front surface of the semiconductor substrate 40 and protects the front surface of the semiconductor substrate 40. A portion of the source electrode 15 is exposed from an opening of the passivation film 35 and constitutes a source pad. A drain electrode (second electrode) 17 is provided on the entire back surface (back surface of the n⁺-type starting substrate 41) of the semiconductor substrate 40.

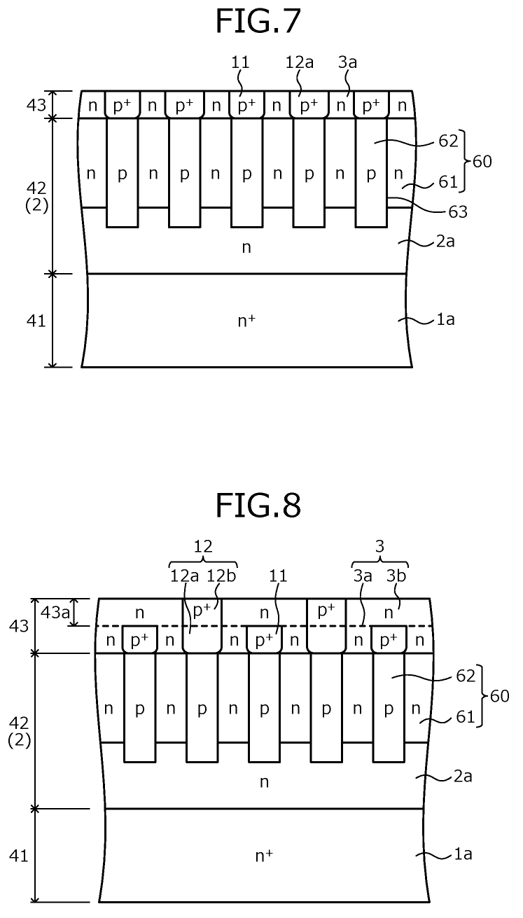

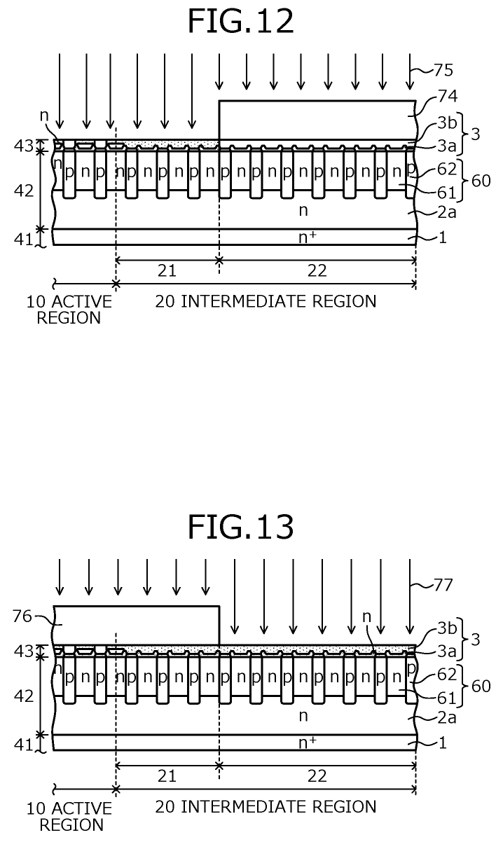

Next, a method of manufacturing the silicon carbide semiconductor device 50 according to the first embodiment is described with reference to FIGS. 1 to 11. FIGS. 7, 8, 9, 10, and 11 are cross-sectional view depicting states of the silicon carbide semiconductor device according to the first embodiment during manufacture. FIGS. 12 and 13 are cross-sectional views of other states of the silicon carbide semiconductor device according to the first embodiment during manufacture. In FIGS. 7 to 9, only the active region 10 is depicted. FIGS. 10 to 13 depict the intermediate region 20.

First, as depicted in FIG. 7, the n⁺-type starting substrate 41, which constitutes the n⁺-type drain region 1, is prepared. The n⁺-type starting substrate 41, for example, may have a crystalline structure that is a 4-layer cyclic hexagonal crystalline structure (4H-SiC) of a silicon carbide and a front surface that is a (0001) plane, a so-called Si face. Next, on the front surface of the n⁺-type starting substrate 41, the n-type epitaxial layer 42 constituting the drift layer 2 is epitaxially grown (formed).

Next, for example, an etching mask (not depicted) opened at portions corresponding to formation regions of the p-type regions 62 of the parallel pn layer 60 is formed at the surface of the epitaxial layer 42 by photolithography and etching, using, for example, an oxide film, etc. Next, the epitaxial layer 42, for example, is dry etched using the etching mask, whereby trenches (SJ trenches) 63 that extend in a striped pattern in the second direction Y are formed.

Portions of the epitaxial layer 42 remaining between the SJ trenches 63 constitute the n-type regions 61 of the parallel pn layer 60. A portion of the epitaxial layer 42 closer to the n⁺-type starting substrate 41 than are bottoms of the SJ trenches 63 constitutes a normal n-type drift region (the portion 2a of the drift layer 2 between the parallel pn layer 60 and the n⁺-type starting substrate 41) that is free of the SJ structure. Subsequently, the etching mask used for forming the SJ trenches 63 is removed.

Before formation of the epitaxial layer 42, on the front surface of the n⁺-type starting substrate 41, another n-type epitaxial layer constituting an n-type buffer region (not depicted) may be epitaxially grown. In this instance, the SJ trenches 63 may be formed to penetrate through the epitaxial layer 42 epitaxially grown on this other n-type epitaxial layer constituting the n-type buffer region, and to reach the n-type buffer region in the depth direction Z.

Next, a p-type epitaxial layer is epitaxially grown (formed), and the SJ trenches 63 are embedded with the p-type epitaxial layer. Next, excess portions of the p-type epitaxial layer on the surface of the epitaxial layer 42 are removed, leaving only the p-type epitaxial layer constituting the p-type regions 62 of the parallel pn layer 60 in the SJ trenches 63. By the processes up to here, the epitaxial layer 42 including the parallel pn layer 60 and constituting the drift layer 2 is formed.

The parallel pn layer 60 may be formed by forming the p-type epitaxial layer 42 on the n⁺-type starting substrate 41, forming the SJ trenches 63 that penetrate through the epitaxial layer 42 in the depth direction Z, leaving the portions that constitute the p-type regions 62, and embedding in the SJ trenches 63, the n-type epitaxial layer that constitutes the n-type regions 61. In this instance, the entire epitaxial layer 42 is set as the parallel pn layer 60 so that no p-type region remains between the n⁺-type starting substrate 41 and the parallel pn layer 60.

Instead of the trench-embedding epitaxial technique, the parallel pn layer 60 may be formed by a multi-stage epitaxial method. In the multi-stage epitaxial method, an n-type epitaxial layer constituting the n-type regions 61 may be made thicker in stages until a predetermined thickness is achieved by multiple stages of epitaxial growth, and for each stage of epitaxial growth, ion implantation for selectively forming the p-type regions 62 (or the n-type regions 61 and the p-type regions 62) may be repeatedly performed.

Next, on the parallel pn layer 60, the n⁻-type epitaxial layer 43 is epitaxially grown (formed). Next, in the active region 10, the p⁺-type regions 11, 12a are selectively formed in surface regions of the n⁻-type epitaxial layer 43 by photolithography and ion-implantation of a p-type impurity. The p⁺-type regions 11 and the p⁺-type regions 12a are disposed alternating one another repeatedly in the first direction X (refer to FIG. 2).

Further, concurrently with the formation of the p⁺-type regions 11, 12a, p⁺-type regions constituting the protrusions 13a (refer to FIG. 5) of the p⁺-type region 13 are selectively formed in surface regions of the n⁻-type epitaxial layer 43, in the intermediate region 20. The p⁺-type regions constituting the protrusions 13a of the p⁺-type region 13 are disposed apart from one another at predetermined intervals in the first direction X, at positions respectively facing the n-type regions 61 and the p-type regions 62 of the parallel pn layer 60 in the depth direction Z.

Next, n-type regions 3a are formed in surface regions of the n⁻-type epitaxial layer 43 by photolithography and ion-implantation of an n-type impurity. The n-type regions 3a are formed in the entire area of the intermediate region 20 and the active region 10 (refer to FIG. 10). The n-type regions 3a are formed between the p⁺-type regions 11, 12a in the active region 10, and between the protrusions 13a of the p⁺-type region 13 in the intermediate region 20. A sequence in which the n-type regions 3a and the p⁺-type regions 11, 12a, 13 (13a) are formed may interchanged.

Next, as depicted in FIG. 8, the thickness of the n⁻-type epitaxial layer 43 is increased by epitaxial growth. Next, in the active region 10, in a portion 43a by which the thickness of the n⁻-type epitaxial layer 43 is increased, p⁺-type regions 12b are selectively formed by photolithography and ion-implantation of a p-type impurity, the p⁺-type regions 12a and the p⁺-type regions 12b adjacent thereto in the depth direction Z are connected, thereby forming the p⁺-type regions 12.

Further, in the intermediate region 20, concurrently with the formation of the p⁺-type regions 12b, the rest of the p⁺-type region 13 is formed in the entire portion 43a by which the thickness of the n⁻-type epitaxial layer 43 is increased. In the intermediate region 20, all portions constituting the protrusions 13a of the p⁺-type region 13 already formed in the n⁻-type epitaxial layer 43 are connected by the p⁺-type region 13 formed in the entire portion 43a by which the thickness of the n⁻-type epitaxial layer 43 is increased (refer to FIG. 5).

Next, by photolithography and ion-implantation of an n-type impurity, n-type regions 3b are formed in the portion 43a by which the thickness of the n⁻-type epitaxial layer 43 is increased and the n-type regions 3a and the n-type regions 3b adjacent thereto in the depth direction Z are connected, whereby the n-type current spreading regions 3 are formed. The n-type regions 3b are formed in the entire area of the intermediate region 20 and the active region 10 (refer to FIG. 10). In FIG. 10, reference numeral 71 is the ion implantation for forming the n-type regions 3a, 3b.

Next, an ion implantation mask 72 having openings in the gate region 22 of the intermediate region 20 is formed on the surface of the n⁻-type epitaxial layer 43. Next, an n-type impurity is again implanted in the n-type current spreading regions 3 in the gate region 22 by an ion implantation 73 using the ion implantation mask 72, whereby the impurity concentration of the n-type current spreading regions 3 in the gate region 22 is increased to be higher than the impurity concentration of the n-type current spreading regions 3 in other areas (portions in the active region 10 and the peripheral contact region 21) (refer to FIG. 11).

A dose amount of the ion implantation 73 is set to be about, for example, 0.3 times to 0.7 times a dose amount of the ion implantation 71, whereby the impurity concentration of the n-type current spreading regions 3 in the gate region 22 may be set to the suitable impurity concentration described above (an impurity concentration that is about 1.3 times to 1.7 times the impurity concentration of the portions of the n-type current spreading regions 3 in the active region 10 and the peripheral contact region 21).

The formation of the ion implantation mask 72 and the ion implantation 73 may be performed for the formation of the n-type regions 3a and for the formation of the n-type regions 3b. Therefore, the sequence in which the ion implantation 73 for increasing the impurity concentration of the n-type regions 3a in the gate region 22, the formation of the p⁺-type regions 12b, 13, the formation of the n-type regions 3b, and the ion implantation 73 for increasing the impurity concentration of the n-type regions 3b in the gate region 22 are performed may be interchanged.

Alternatively, after the n-type regions 3a, 3b are formed only in the active region 10 and the peripheral contact region 21 of the intermediate region 20 (refer to FIG. 12), the n-type regions 3a, 3b in the gate region 22 may be formed by a single session of an ion implantation 77 to have the suitable impurity concentration of the n-type current spreading regions 3 in the gate region 22 described above (refer to FIG. 13). In other words, the dose amount of the ion implantation 77 suffices to be set to be about, for example, 1.3 times to 1.7 times the dose amount of the ion implantation 71.

In the other example depicted in FIGS. 12 and 13, formation of an ion implantation mask 74 for forming the n-type regions 3a, 3b in only the active region 10 and the peripheral contact region 21 and an ion implantation 75 may be performed for the formation of the n-type regions 3a and for the formation of the n-type regions 3b. Formation of an ion implantation mask 76 for forming the n-type regions 3a, 3b in the gate region 22 and the ion implantation 77 may be performed for the formation of the n-type regions 3a and for the formation of the n-type regions 3b.

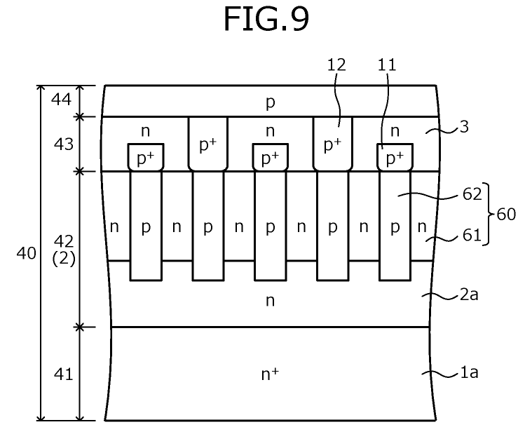

Next, as depicted in FIG. 9, the p-type epitaxial layer 44 constituting the p-type base region 4 is epitaxially grown on the n⁻-type epitaxial layer 43. As a result, the epitaxial layer 42, the n⁻-type epitaxial layer 43, and the p-type epitaxial layer 44 are sequentially stacked on the front surface of the n⁺-type starting substrate 41, whereby the semiconductor substrate (semiconductor wafer) 40 having the parallel pn layer 60 in the epitaxial layer 42 constituting the drift layer 2 is fabricated.

Next, a portion of the p-type epitaxial layer 44 in the edge termination region 30 is removed by etching to form at the front surface of the semiconductor substrate 40, the drop 31 where the portion of the front surface in the edge termination region 30 (the second surface portion 40b) is lower than that on the active region 10 side (the first surface portion 40a) (refer to FIG. 2). In the edge termination region 30, the n⁻-type epitaxial layer 43 is exposed at the second surface portion 40b that newly becomes the front surface of the semiconductor substrate 40.

The portion (the third surface portion 40c) of the front surface of the semiconductor substrate 40 between the first surface portion 40a and the second surface portion 40b, for example, may have an obtuse angle relative to the first and the second surface portions 40a, 40b. At the second and the third surface portions 40b, 40c of the front surface of the semiconductor substrate 40, the p-type base region 4 and the p⁺-type region 13 are exposed. A portion of the n⁻-type epitaxial layer 43 may be slightly exposed at the second surface portion 40b of the front surface of the semiconductor substrate 40 due to the etching when forming the drop 31.

Next, a process that is a combination of photolithography and ion implantation is repeatedly performed under different conditions to selectively form the n⁺-type source regions 5, the p⁺⁺-type contact regions 6, the p⁺-type peripheral contact region 21b, the p-type regions (p⁻-type region 33) of the JTE structure 32, and the n⁺-type stopper region 34. The n⁺-type source regions 5, the p⁺⁺-type contact regions 6, and the p⁺-type peripheral contact region 21b are each formed in surface regions of the p-type epitaxial layer 44.

A portion of the p-type epitaxial layer 44 excluding the n⁺-type source regions 5, the p⁺⁺-type contact regions 6, and the p⁺-type peripheral contact region 21b constitutes the p-type base region 4. The p-type regions of the JTE structure 32 and the n⁺-type stopper region 34 are each formed in surface regions of the n⁻type epitaxial layer 43 exposed at the second surface portion 40b of the front surface of the semiconductor substrate 40 in the edge termination region 30.

Next, a heat treatment (hereinafter, activation annealing) for activating the impurities ion-implanted in the epitaxial layers 43, 44 is performed. Next, in the active region 10, the gate trenches 7 that penetrate through the n⁺-type source regions 5 and the p-type base region 4 from the front surface of the semiconductor substrate 40 and reach the p⁺-type regions 11 in the n-type current spreading regions 3 are formed. Next, the gate insulating film 8 is formed along the front surface of the semiconductor substrate 40 and inner walls of the gate trenches 7.

Next, the polysilicon layer that is deposited on the front surface of the semiconductor substrate 40 so as to be embedded in the gate trenches 7 is etched and portions thereof constituting the gate electrodes 9 are left in the gate trenches 7. In the intermediate region 20 and the edge termination region 30, a field oxide film (not depicted) is formed on the front surface of the semiconductor substrate 40. The gate runner 22a constituted by the polysilicon layer on the field oxide film is formed in the intermediate region 20, (refer to FIGS. 1, 2).

Next, the interlayer insulating film 14 is formed on the entire front surface of the semiconductor substrate 40. Next, by a general method, surface electrodes (the source electrode 15, the gate pad 16 (refer to FIG. 1), the gate wiring layer 22b (refer to FIGS. 1, 2) and the drain electrode 17) are formed on the main surfaces of the semiconductor substrate 40. The gate electrodes 9 are electrically connected to the gate pad 16, via the gate runner 22a and the gate wiring layer 22b.

Next, a portion of the front surface of the semiconductor substrate 40 excluding a portion of the source electrode 15 (portion constituting the source pad), the gate pad 16, and the gate wiring layer 22b is covered and protected by the passivation film 35. Thereafter, the semiconductor wafer (the semiconductor substrate 40) is diced (cut) into individual chips, whereby the silicon carbide semiconductor device 50 depicted in FIGS. 1 to 6 is completed.

As described above, according to the first embodiment, the protrusions that protrude toward the parallel pn layer are formed in the p⁺-type region provided between the p-type base region and the parallel pn layer in the intermediate region, whereby in the parallel pn layer, in a portion thereof facing the semiconductor substrate, electric field strength distribution of the intermediate region is set to be substantially the same as the electric field strength distribution of the active region. In addition, the n-type current spreading regions are provided in the entire active region and the entire intermediate region, and the impurity concentration of the portion of the n-type current spreading regions in the gate region of the intermediate region is set to be higher than that other portions thereof (active region and the peripheral contact region of the intermediate region).

As a result, the electric field strength in the active region may be increased to be greater than the electric field strength in the intermediate region, facilitating avalanche breakdown in the active region. By the avalanche breakdown in the active region, hole current (avalanche current) flows in in the entire active region, thereby enabling the hole current density in the peripheral contact region to be reduced and current concentration in the peripheral contact region to be suppressed. As a result, the avalanche capability in the intermediate region is enhanced, thereby enabling the avalanche capability of the entire silicon carbide semiconductor device to be enhanced.

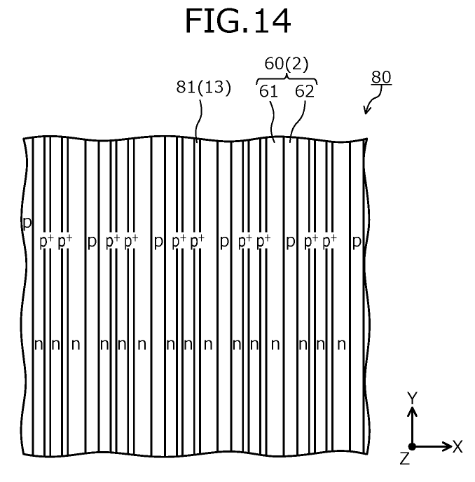

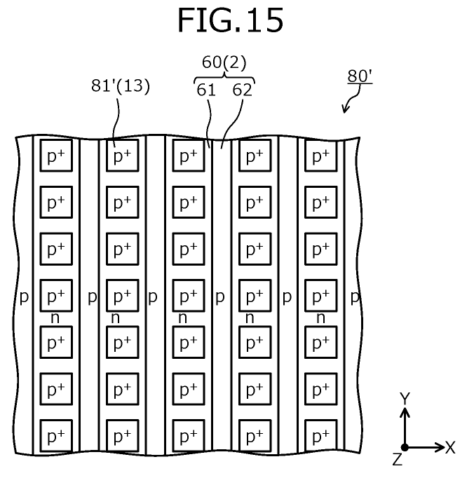

A structure of a silicon carbide semiconductor device according to a second embodiment is described. FIGS. 14 and 15 are plan views depicting a layout when the silicon carbide semiconductor device according to the second embodiment is viewed from the front side of the semiconductor substrate. Silicon carbide semiconductor devices 80, 80' according to the second embodiment differ from the silicon carbide semiconductor device 50 according to the first embodiment (refer to FIG. 4A) in that layouts of protrusions 81, 81' of the p⁺-type region 13 differ from the layout of the silicon carbide semiconductor device 50.

In the silicon carbide semiconductor device 80 according to the second embodiment depicted in FIG. 14, the p⁺-type region 13 has, at portions thereof respectively facing the n-type regions 61 and the p-type regions 62 of the parallel pn layer 60 in the depth direction Z, the protrusions 81 that protrude toward the parallel pn layer 60. The protrusions 81 of the p⁺-type region 13, similarly to the first embodiment, are disposed in a striped pattern extending in the second direction Y, which is the same direction in which the n-type regions 61 and the p-type regions 62 of the parallel pn layer 60 extend.

The protrusions 81 of the p⁺-type region 13 face the n-type regions 61 in the depth direction Z and are disposed in plural (in FIG. 14, two (2)) between and apart from each adjacent two of the protrusions 81 facing the p-type regions 62 in the depth direction Z. Thus, multiple linear shaped protrusions 81 of the p⁺-type region 13 face each of the n-type regions 61 in the depth direction Z. The number of protrusions 81 of the p⁺-type region 13 is greater than the number of the n-type regions 61 and the p-type regions 62 of the parallel pn layer 60 in the intermediate region 20.

In the silicon carbide semiconductor device 80' according to the second embodiment depicted in FIG. 15, the p⁺-type region 13 has, at portions thereof respectively facing the n-type regions 61 and the p-type regions 62 of the parallel pn layer 60 in the depth direction Z, the protrusions 81' that protrude toward the parallel pn layer 60. The protrusions 81' of the p⁺-type region 13 face the n-type regions 61 in the depth direction Z and, for example, each has a substantially rectangular shape in a plan view, the protrusions 81' being disposed scattered at a predetermined interval in the second direction Y, forming a matrix-like pattern.

The silicon carbide semiconductor device 80' according to the second embodiment depicted in FIG. 15 may be applied to the silicon carbide semiconductor device 80 according to the second embodiment depicted in FIG. 14 and the multiple protrusions facing a respective one of the n-type regions 61 of the parallel pn layer 60 in the depth direction Z may be scattered in the second direction Y. In other words, sets of protrusions may be disposed respectively facing the n-type regions 61 of the parallel pn layer 60 in the depth direction Z, forming a matrix-like pattern.

While the protrusions 81, 81' of the p⁺-type region 13 facing the p-type regions 62 in the depth direction Z are not depicted, in FIG. 14, each of the protrusions 81 of the p⁺-type region 13 facing one of the p-type regions 62 in the depth direction Z extends linearly in the second direction Y, similarly to the first embodiment. In FIG. 15, each of the protrusions 81' of the p⁺-type region 13 facing one of the p-type regions 62 in the depth direction Z extends linearly in the second direction Y, similarly to the first embodiment.

A method of manufacturing the silicon carbide semiconductor devices 80, 80' according to the second embodiment may be implemented by changing, in the method of manufacturing the silicon carbide semiconductor device 50 according to the first embodiment, the pattern of the ion implantation mask used in the ion implantation for forming the protrusions 81, 81' of the p⁺-type region 13 in the intermediate region.

As described above, according to the second embodiment, effects similar to those of the first embodiment may be obtained even when, in the intermediate region, the layout (striped pattern or matrix-like pattern) of the protrusions of the p⁺-type region provided between the parallel pn layer and the p-type base region (the p⁺-type region electrically connecting the p-type base region and the p-type regions of the JTE structure) is variously changed, said protrusions of the p⁺-type region facing the n-type regions of the parallel pn layer in the depth direction.

Further, according to the second embodiment, in the p⁺-type region provided between p-type base region and the parallel pn layer in the intermediate region, multiple protrusions are provided facing one n-type region of parallel pn layer in the depth direction, whereby the ratio that the n-type current spreading regions between the parallel pn layer and the p-type base region occupy in the intermediate region may be increased. As a result, the effective thickness of the drift region in the intermediate region is increased and the electric field strength in the active region becomes higher than that in the intermediate region, whereby avalanche breakdown in the active region may be further enhanced.

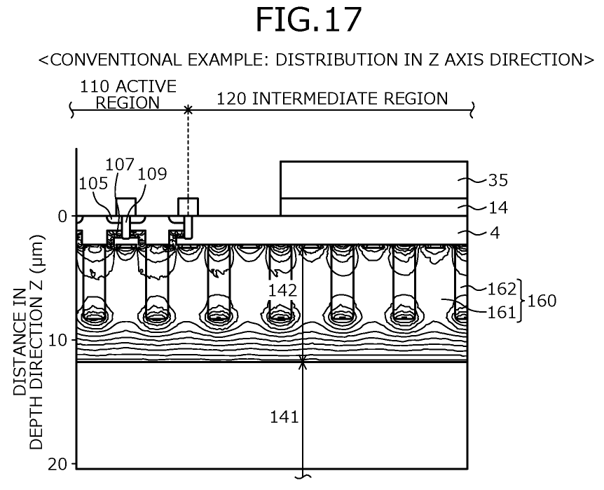

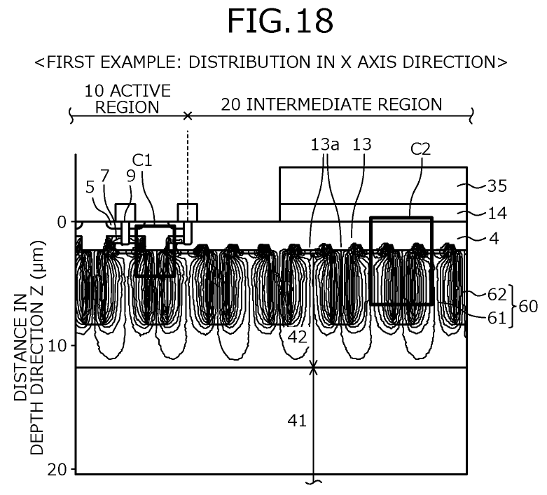

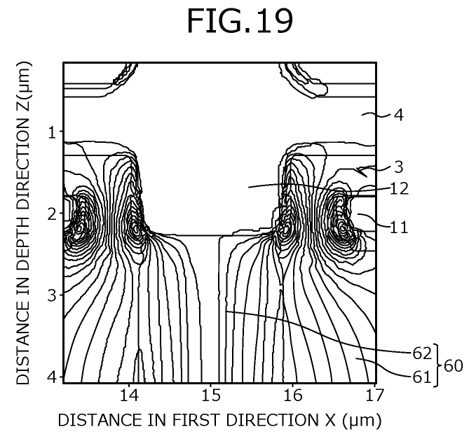

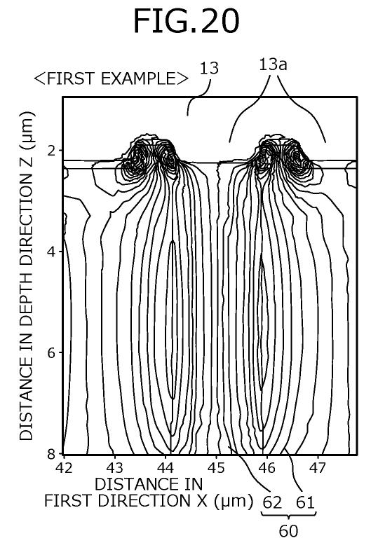

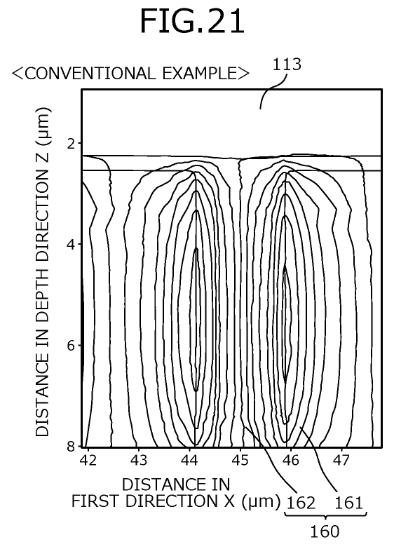

The electric field strength of the intermediate region 20 of the silicon carbide semiconductor device 50 according to the first embodiment (refer to FIGS. 1 to 6) was verified. FIGS. 16 and 17 are distribution diagrams depicting results of simulating electric field strength in the depth direction for a first example and a conventional example. FIGS. 18 and 21 are distribution diagrams depicting results of simulating electric field strength in a first direction for the first example and the conventional example. FIG. 19 is an enlarged view of an area within a rectangular frame C1 depicted in FIG. 18. FIG. 20 is an enlarged view of an area within a rectangular frame C2 depicted in FIG. 18.

For the active region 10 and the intermediate region 20 of the silicon carbide semiconductor device 50 according to the first embodiment described above (hereinafter, the first example), electric field strength distribution in the depth direction Z is shown in FIG. 16 while electric field strength distribution in the first direction X is shown in FIGS. 18 to 20. In the first example, to obtain the electric field strength distribution obtained by the protrusions 13a provided at an interface between the p⁺-type region 13 and the drift region, the impurity concentration of the n-type current spreading regions 3 was assumed to be the same impurity concentration spanning the entire active region 10 and the entire intermediate region 20 (the peripheral contact region 21 and the gate region 22).

For comparison, for the conventional silicon carbide semiconductor device 150 (hereinafter, the conventional example, refer to FIGS. 30 to 33), the electric field strength distribution in the depth direction Z for the active region 110 and the intermediate region 120 thereof is depicted in FIG. 17 while the electric field strength distribution in the first direction X for the intermediate region 120 is depicted in FIG. 21. The electric field strength distribution in the first direction X for the active region 110 of the conventional example is the same as the electric field strength distribution in the first direction X for the active region 10 of the first example, and reference numerals in FIG. 19 are for 100- series. The conventional example differs from the second example on the following two points.

The first difference is that the interface between the p⁺-type region 113 and the drift region is a flat surface parallel to the front surface of the semiconductor substrate 140. The second difference is that the n-type current spreading regions 103 are provided only in the active region 110 and the peripheral contact region 121 of the intermediate region 120, and are not provided in the gate region 122 of the intermediate region 120. The impurity concentration of the n-type current spreading regions 103 is the same impurity concentration spanning the entire active region 110 and the entire peripheral contact region 121 of the intermediate region 120.

In the conventional example, it was confirmed that electric field strength distribution in the depth direction Z and in the first direction X for the parallel pn layer 160 in the front side of the semiconductor substrate 140 in the intermediate region 120 differs from the electric field strength distribution that in the active region 110, and the electric field strength in the intermediate region 120 is greater than that in the active region 110 (FIGS. 17, 19, 21). On the other hand, in the first example, it was confirmed that in the depth direction Z and in the first direction X, the electric field strength distribution of the parallel pn layer 60 in the front side of the semiconductor substrate 40 in the intermediate region 20 is substantially the same as that for the active region 10 (FIGS. 16, 18 to 20).

While the electric field strength distribution in the second direction Y is not depicted, in the first example, in the front side of the parallel pn layer 60 in the front side of the semiconductor substrate 40, for the electric field strength distribution in the second direction Y, the electric field strength distribution in the intermediate region 20 is substantially the same as the electric field strength distribution in the active region 10. Therefore, like the first example, it was confirmed that due to the protrusions 13a being formed in the p⁺-type region 13 of the intermediate region 20, in the front side of the parallel pn layer 60 in the front side of the semiconductor substrate 40, the electric field strength distribution in the intermediate region 20 may be set to be substantially the same as the electric field strength distribution in the active region 10.

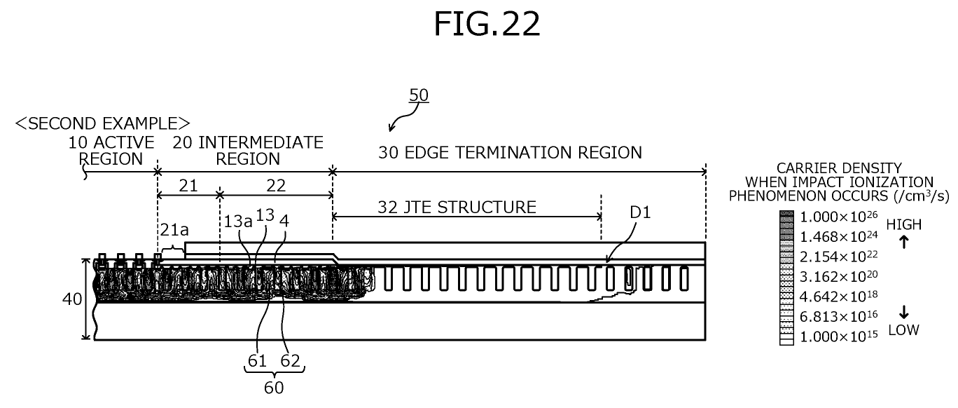

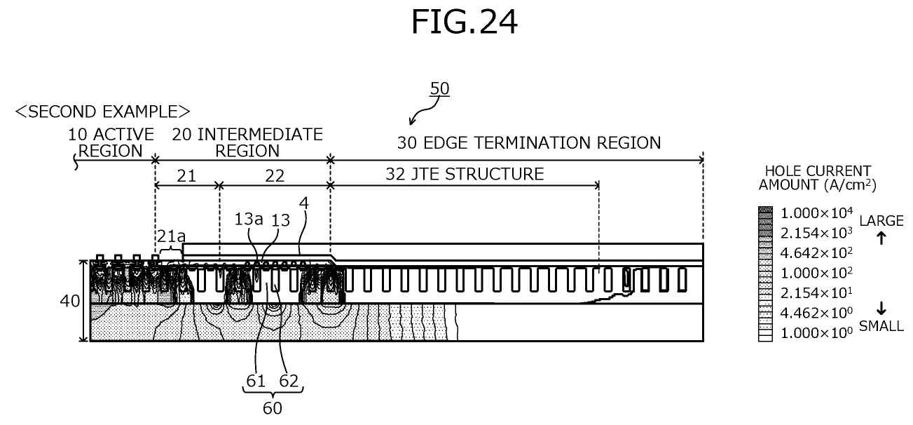

Minority carrier (hole) current amount in the intermediate region 20 during avalanche breakdown of the silicon carbide semiconductor device 50 according to the first embodiment (refer to FIGS. 1 to 6) was verified. FIGS. 22 and 23 are distribution diagrams depicting results of simulating carrier density during avalanche breakdown (during occurrence of the impact ionization phenomenon) in a second example and the conventional example. FIGS. 24 and 25 are distribution diagrams depicting results of simulation of the hole current amount during avalanche breakdown in the second example and the conventional example.

Carrier density distribution and hole current amount distribution during avalanche breakdown in the above-described silicon carbide semiconductor device 50 according to the first embodiment (hereinafter, the second example) are shown in FIGS. 22 and 24, respectively. The second example differs from the first example in that the impurity concentration of the n-type current spreading regions 3 in the gate region 22 is set to be 1.5 times that of the n-type current spreading regions 3 in the active region 10 and the peripheral contact region 21. For comparison, the carrier density distribution and the hole current amount distribution during avalanche breakdown in the conventional example described above are shown in FIGS. 23 and 25, respectively.

In the conventional example, increase of the carrier density due to the impact ionization phenomenon is greater in the intermediate region 120 than in the active region 110, and avalanche breakdown occurs in the gate region 122 (FIG. 23). It was confirmed that due to this avalanche breakdown, the hole current (avalanche current) increases suddenly in the gate region 122 and a large hole current is discharged from the p⁺-type peripheral contact region 121b to the source electrode 115, via the p⁺-type region 113 of the intermediate region 120, whereby the hole current concentrates in the p⁺-type region 113 and the peripheral contact 121a (FIG. 25).

On the other hand, in the second example, it was confirmed that increase of the carrier density due to the impact ionization phenomenon is greater in the active region 10 than in the intermediate region 20, and avalanche breakdown is facilitated in the active region 10 (FIG. 22). It was confirmed that due to the avalanche breakdown, mainly, the hole current (avalanche current) suddenly increases in the active region 10, and the hole current is distributed to the contact portions of the active region 10 and the peripheral contact 21a of the intermediate region 20 and is discharged to the source electrode 15, whereby concentration of the hole current in the peripheral contact 21a of the intermediate region 20 is suppressed (FIG. 24).

A reason that avalanche breakdown is facilitated in the active region 10 of the second example is as follows. The impurity concentration of the n-type current spreading regions 3 in the gate region 22 is relatively high, whereby the effective thickness of the drift region is thicker in the intermediate region 20 than in the active region 10, enabling the electric field strength of the intermediate region 20 to be set relatively small. Further, the electric field strength distribution of the active region 10 and the intermediate region 20 are substantially the same (refer to FIGS. 16, 18 to 20), whereby the electric field strength of the active region 10 may be set to be greater than the electric field strength of the intermediate region 20.

Further, in the second example and the conventional example, it was confirmed that by setting the SJ structure (the drift layer 2 being set as the parallel pn layer 60), avalanche breakdown is suppressed at an outer end (outer end of the outermost p-type region configuring the JTE structure 32) D1, D101 of the JTE structures 32, 132. Further, the inventor confirmed that the SJ structure may face the JTE structure 32 in the depth direction Z and even when the SJ structure is not provided to the end of the semiconductor substrate 40, the above results for the second example (FIGS. 22, 24) are obtained.

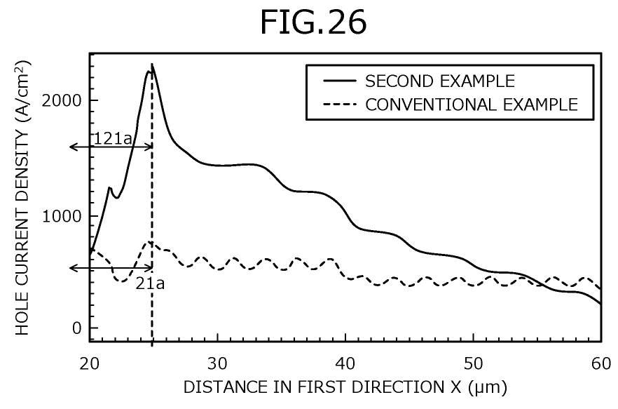

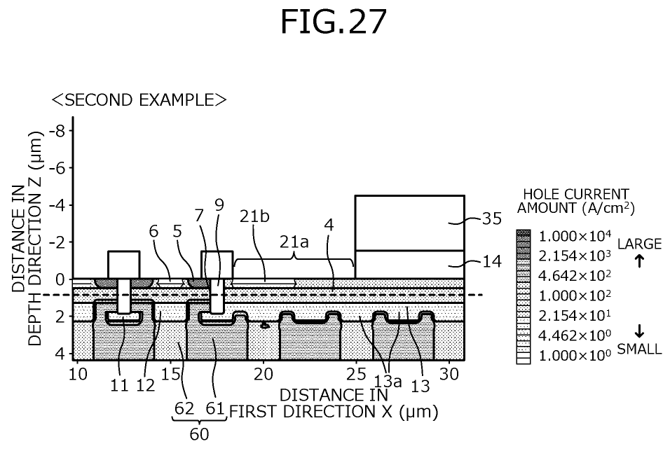

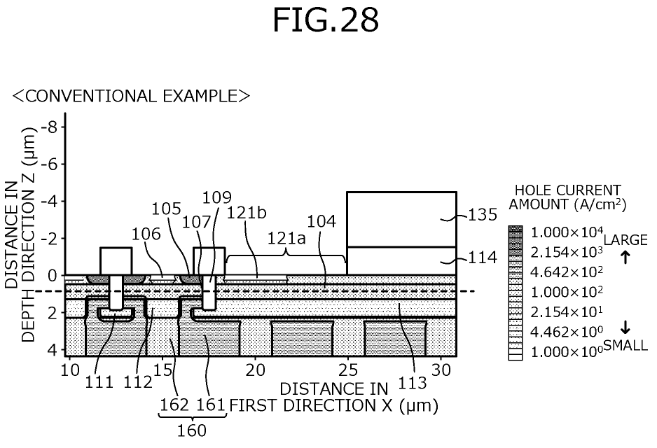

Distribution of hole current density near the peripheral contacts 21a, 121a of the second example and the conventional example are shown in FIG. 26. FIG. 26 is a distribution diagram depicting results of simulation of hole current density near the peripheral contact in the second example. FIGS. 27 and 28 are distribution diagrams depicting the impurity concentration near the peripheral contacts in the second example and the conventional example, respectively. In FIGS. 26, 27, and 28, horizontal axes represent distance in the first direction X and indicate the same position in the first direction X. In FIG. 26, a vertical axis represents hole current density. In FIGS. 27 and 28, vertical axes represent distance (depth) in the depth direction Z.

From the results depicted in FIG. 26, it was confirmed that in the second example, compared to the conventional example, hole current density in the peripheral contact 21a may be reduced. In this manner, during the off state, avalanche breakdown is caused in the active region 10 and a majority of hole current (avalanche current) flows mainly in the active region 10, whereby hole current density in the peripheral contact 21a may be reduced and the avalanche capability in the intermediate region 20 may be enhanced. As a result, overall avalanche capability of the second example may be enhanced.

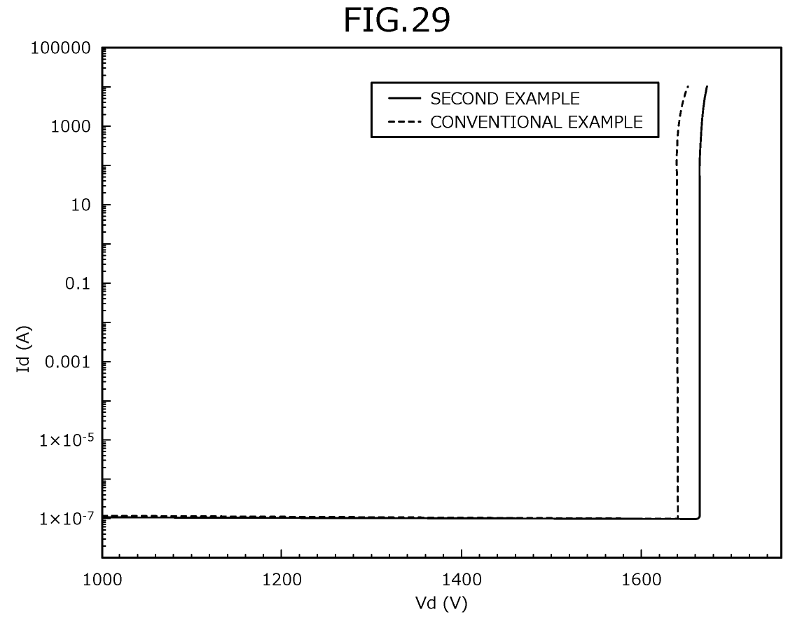

Further, breakdown voltage (static breakdown voltage) of the second example was verified. Voltage-current characteristics of the second example and the conventional example are depicted in FIG. 29. FIG. 29 is a characteristics diagram depicting results of simulation of voltage-current characteristics in the second example. In FIG. 29, a horizontal axis represents drain-source voltage Vd, and a vertical axis represents drain-source current Id. From the results depicted in FIG. 29, it was confirmed that the second example obtained about the same breakdown voltage as that of the conventional example due to the charge balance of the SJ structure. Thus, the second example may enhance the avalanche capability (dynamic breakdown voltage) while maintaining the breakdown voltage.

While not depicted in the figures, the impurity concentration of the n-type current spreading regions 3 in the gate region 22 is set higher than that of the n-type current spreading regions 3 in other regions (in the active region 10 and in the peripheral contact region 21), whereby effects similar to those of the second example are obtained and particularly, when the effective thickness of the n-type current spreading regions 3 in the gate region 22 is 1.3 times to 1.7 times that of the n-type current spreading regions 3 in other regions, the effects are high as confirmed by the inventor. While not depicted, the inventor further confirmed that even in the silicon carbide semiconductor devices 80, 80' according to the second embodiment, effects similar to those of the first and second examples may be obtained.

In the foregoing, the present invention is not limited to the embodiments described and may variously modified within a range not departing from the spirit of the invention. For example, in the embodiments described above, due to shifting of the position of the ion implantation mask (corresponds to reference numeral 72 in FIG. 11, reference numeral 74 in FIG. 12, reference numeral 76 in FIG. 13), etc., not only the n-type current spreading regions in the gate region but also those near the gate region in the peripheral contact region may have a relatively high impurity concentration. Further, the impurity concentration of a normal n-type drift region that does not have the SJ structure and that is between the parallel pn layer and the n⁺-type starting substrate may have an impurity concentration that is higher than that of the n-type regions of the parallel pn layer. Further, the present invention is similarly implemented when the conductive types (n-type, p-type) are reversed.

As described above, in the front side of the parallel pn layer facing the front surface of the semiconductor substrate, the electric field strength distribution in the intermediate region may be set to be substantially the same as the electric field strength distribution in the active region and the electric field strength in the active region may be set to be greater than the electric field strength in the intermediate region. As a result, avalanche breakdown in the active region may be enhanced.

The silicon carbide semiconductor device according to the present invention achieves an effect in that the avalanche capability may be enhanced.

As described above, the silicon carbide semiconductor device according to the present invention is useful for power semiconductor devices with a SJ structure used in power converting equipment, power source devices used in various types of industrial machines and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device, comprising:
a semiconductor substrate containing silicon carbide, the semiconductor substrate having a first main surface and a second main surface that are opposite to each other;
a parallel pn layer in which a plurality of first-conductivity-type regions and a plurality of second-conductivity-type regions alternate with one another repeatedly in a first direction that is parallel to the first main surface of the semiconductor substrate, the parallel pn layer being provided in the semiconductor substrate, spanning an active region and a termination region that surrounds a periphery of the active region;
a first surface portion of the first main surface of the semiconductor substrate, the first surface portion excluding a portion of the first main surface in the termination region;
a second surface portion of the first main surface of the semiconductor substrate, the second surface portion being the portion of the first main surface in the termination region;
a stepped portion provided on the first main surface of the semiconductor substrate, between the first surface portion and the second surface portion, at which the second surface portion is recessed in a depth direction with respect to the first surface portion toward the second main surface of the semiconductor substrate;
a first semiconductor region of a second conductivity type, provided between the first surface portion of the semiconductor substrate and the parallel pn layer, the first semiconductor region extending from the active region to an intermediate region between the active region and the termination region, and reaching the stepped portion;
a plurality of second semiconductor regions of a first conductivity type, provided in the active region, between and in contact with the first semiconductor region and the parallel pn layer;
a plurality of third semiconductor regions of the first conductivity type, selectively provided in the active region, between the first surface portion of the semiconductor substrate and the first semiconductor region;
a plurality of trenches that penetrate through the plurality of third semiconductor regions and the first semiconductor region, and reach the plurality of second semiconductor regions;
a gate insulating film provided in each of the plurality of trenches;
a plurality of gate electrodes provided on the gate insulating film in respective ones of the plurality of trenches;
a plurality of first high-concentration regions of the second conductivity type, provided between bottoms of the plurality of trenches and the parallel pn layer, each of the plurality of first high-concentration regions facing the bottom of a respective one of the plurality of trenches in the depth direction and having an impurity concentration that is higher than an impurity concentration of the first semiconductor region;
a plurality of second high-concentration regions of the second conductivity type, provided between the first semiconductor region and the parallel pn layer in the active region so as to be in contact with the first semiconductor region and apart from the plurality of trenches and the plurality of first high-concentration regions, each of the plurality of second high-concentration regions having an impurity concentration that is higher than the impurity concentration of the first semiconductor region;
a third high-concentration region of the second conductivity type, provided between the first semiconductor region and the parallel pn layer in the intermediate region, the third high-concentration region being in contact with the first semiconductor region and electrically connected to both the first high-concentration regions and the second high-concentration regions, the third high-concentration region surrounding the periphery of the active region and having an impurity concentration that is higher than the impurity concentration of the first semiconductor region;
a fourth semiconductor region of the second conductivity type, selectively provided between the second surface portion of the semiconductor substrate and the parallel pn layer, the fourth semiconductor region surrounding the periphery of the active region with the intermediate region intervening therebetween, the fourth semiconductor region being electrically connected to the first semiconductor region via the third high-concentration region and configuring the voltage withstanding structure;
a first electrode electrically connected to the plurality of third semiconductor regions and the first semiconductor region; and
a second electrode provided on the second main surface of the semiconductor substrate, wherein
the intermediate region has a first intermediate region in which an electrical contact between the first electrode and the first semiconductor region is formed, and a second intermediate region that is between the first intermediate region and the termination region,
the third high-concentration region has a first portion that faces at least one of the plurality of first-conductivity-type regions of the parallel pn layer, and a second portion that faces at least one of the plurality of second-conductivity-type regions of the parallel pn layer, the first and second portions respectively having a first protrusion and a second protrusion, each protruding in the depth direction toward the parallel pn layer,
the plurality of second semiconductor regions extend from the active region to the intermediate region and reach the stepped portion,
each of the plurality of second semiconductor regions is between the third high-concentration region and the parallel pn layer, positioned between a respective adjacent pair of protrusions of the plurality of protrusions of the third high-concentration region, and is adjacent to a corresponding one of the plurality of first-conductivity-type regions of the parallel pn layer in the depth direction, and
among the plurality of second semiconductor regions, ones in the second intermediate region have an impurity concentration that is higher than an impurity concentration of others outside the second intermediate region.

2. The silicon carbide semiconductor device according to claim 1, wherein
the impurity concentration of the ones of the plurality of second semiconductor regions in the second intermediate region is 1.3 times to 1.7 times the impurity concentration of the others of the plurality of second semiconductor regions outside the second intermediate region.

3. The silicon carbide semiconductor device according to claim 1, wherein
the first protrusion and the second protrusion are each provided in plurality, and
each first protrusion faces in the depth direction a different one of the plurality of first-conductivity-type regions of the parallel pn layer, and each second protrusion faces in the depth direction a different one of the plurality of second-conductivity-type regions of the parallel pn layer.

4. The silicon carbide semiconductor device according to claim 1, wherein
the first protrusion and the second protrusion are each provided in plurality, and
at least two of the plurality of first protrusions face in the depth direction a same one of the plurality of first-conductivity-type regions of the parallel pn layer, and at least two of the plurality of second protrusions face in the depth direction a same one of the plurality of second-conductivity-type regions of the parallel pn layer.

5. The silicon carbide semiconductor device according to claim 1, wherein
the first-conductivity-type regions and the second-conductivity-type regions of the parallel pn layer each extend linearly in a second direction that is parallel to the first main surface of the semiconductor substrate and orthogonal to the first direction, and
the first and second portions of the third high-concentration region having the first and second protrusions each extend linearly in the second direction.

6. The silicon carbide semiconductor device according to claim 1, wherein
the first-conductivity-type regions and the second-conductivity-type regions of the parallel pn layer each extends linearly in a second direction that is parallel to the first main surface of the semiconductor substrate and orthogonal to the first direction, and
the first and second portions of the third high-concentration region each extend linearly, and the first and second protrusions are provided in plurality and scattered on the first and second portions in the second direction.

7. The silicon carbide semiconductor device according to claim 1, further comprising:
a gate runner formed by a polysilicon layer and provided in the second intermediate region, on the first main surface of the semiconductor substrate via an insulating layer, wherein
the second intermediate region provides an electrical contact between the plurality of gate electrodes and the gate runner.
